(19) United States
(12) Patent Application Publication
(10) Pub. No.: US 2025/0096127 A1
(43) Pub. Date: Mar. 20, 2025

(54) BACKSIDE FUSE STRUCTURE UTILIZING BACKSIDE CONTACT

(71) Applicant: INTERNATIONAL BUSINESS MACHINES CORPORATION, ARMONK, NY (US)

(72) Inventors: Lawrence A. Clevenger, Saratoga Springs, NY (US); Dan Moy, Bethel, CT (US); JENS HAETTY, Halfmoon, NY (US); Christopher Murphy, Red Hook, NY (US); Ruilong Xie, Niskayuna, NY (US); Nicholas Anthony Lanzillo, Wynantskill, NY (US); Huai Huang, Clifton Park, NY (US); Hosadurga Shobha, Niskayuna, NY (US); Atharv Jog, Albany, NY (US)

(21) Appl. No.: 18/470,664

(22) Filed: Sep. 20, 2023

(51) Int. Cl. H01L 23/525

(52) U.S. Cl. CPC H01L 23/5256

(57) ABSTRACT

A semiconductor integrated circuit (IC) device includes a backside fuse structure and a backside contact. The backside fuse structure is located within the backside of the semiconductor IC device vertically between a transistor there above and a backside back end of the line (BEOL) network. The backside fuse structure includes a fuse wire and a deep via contact that is connected to both the fuse wire and to a frontside BEOL network. The backside contact is connected to the transistor, to the backside BEOL network, and to the fuse wire. The backside fuse structure may be in a non-programmed state or a programmed state. When in a non-programmed state, an open circuit exists that prevents current flow through the fuse wire or through the backside contact.

### BACKGROUND

The present disclosure relates to fabrication methods and resulting structures for semiconductor devices. More specifically, the present disclosure relates to fabrication methods and resulting semiconductor integrated circuit (IC) devices that include a backside fuse structure, such as an electronic fuse (eFUSE).

An eFUSE is a microscopic fuse put into a semiconductor IC device, such as a computer chip, and may provide for the dynamic real-time reprogramming of the semiconductor IC device. Typically, logic is generally “etched” or “hard-wired” into a semiconductor IC device and cannot be changed after the semiconductor IC device has finished being manufactured. By utilizing a set of eFUSE, a semiconductor IC device manufacturer can allow for the circuits on a chip to change while it is in operation. Consequently, eFUSEs may provide semiconductor IC device performance tuning. If certain sub-systems fail, or are taking too long to respond, or are consuming too much power, the semiconductor IC device can instantly change its behavior by blowing or programming one or more eFUSEs. eFUSEs may also be used as a one-time programmable read only memory. This ranges from writing unique information onto the semiconductor IC device, preventing upgrades or downgrades, or the like.

eFUSEs can be respective silicon or metal traces and typically work (by blowing or programming) by electromigration, the phenomenon that electric flow causes the conductor material to move. Although electromigration is generally undesired in semiconductor IC device design as it causes failures, eFUSEs are made of weak traces that are designed to fail before others do.

### SUMMARY

In an embodiment of the present disclosure, a semiconductor integrated circuit (IC) device is presented. The semiconductor IC device includes a fuse structure and a backside contact. The fuse structure includes a fuse wire and a deep via contact that is connected to both the fuse wire and to a frontside back end of the line (BEOL) network. The backside contact is connected to a transistor, to a backside BEOL network, and to the fuse wire. By associating the fuse structure with the backside BEOL network, the presented semiconductor IC device may be further scaled (i.e., shrunk is size) and/or may have reduced signal and/or power wiring routing complexities therein. Further, by placing the fuse wire between the FEOL microdevice and the backside BEOL network, the fuse wire may be located relatively closer to the FEOL microdevice and may require relatively lower (e.g., three to six times lower) programming current compared to known eFUSE placement schemes.

In an example, the fuse wire is between the deep via contact and the backside BEOL network. As such, the fuse wire may be located on the backside of the semiconductor IC device between a front end of the line device and the backside BEOL network, which may reduce signal or wiring routing complexities in the semiconductor IC device.

In an example, a top surface of the fuse wire is connected to a bottom surface of the deep via contact. As such, the fuse wire may be located on the backside of the semiconductor IC device and upon the deep via contact, which may reduce signal or wiring routing complexities in the semiconductor IC device.

In an example, a side surface of the fuse wire is connected to a sidewall of the backside contact. As such, the fuse wire may be located on the backside of the semiconductor IC device above the backside BEOL network and vertically inset with respect to the backside contact, which may reduce signal or wiring routing complexities in the semiconductor IC device.

In an example, a top surface of the backside contact is connected to a source/drain (S/D) region of the transistor. In this way, the backside contact may serve as a terminal to the S/D of the transistor, to the backside BEOL network, and to the fuse wire, which may reduce signal or wiring routing complexities in the semiconductor IC device.

In an example, when the fuse structure is in a non-programmed state, the backside contact is a terminal for routing current through the transistor and for routing current between the frontside BEOL network and the backside BEOL network by way of the fuse wire. In this way, the in the non-programmed state the backside contact may serve as a terminal to the S/D of the transistor, to the backside BEOL network, and to the fuse wire, which may reduce signal or wiring routing complexities in the semiconductor IC device.

In an example, when the fuse structure is in a programmed state, an open circuit exists within the fuse wire that prevents the fuse wire from routing current between the frontside BEOL network and the backside BEOL network. In this manner, semiconductor IC operations associated with current flow between the frontside BEOL network and the backside BEOL network over the fuse wire may be altered, prohibited, or the like.

In an example, when the fuse structure is in a programmed state, an open circuit exists within the backside contact that prevents the backside contact from routing current through the transistor and the backside contact from routing current between the frontside BEOL network and the backside BEOL network by way of the fuse wire. In this manner, semiconductor IC operations associated with current flow through the transistor and between the frontside BEOL network and the backside BEOL network over the fuse wire may be altered, prohibited, or the like.

In an example, a diffusion break region is between the transistor and the deep via contact. In this way, the fuse wire may traverse from the backside contact through the diffusion break region and underneath an associated diffusion break to the deep via contact.

In an example, the fuse wire is underneath a shallow trench isolation (STI) region. As such, the fuse wire may be located upon the STI region on the backside of the semiconductor IC device, which may reduce signal or wiring routing complexities in the semiconductor IC device.

In an example, the fuse wire is coplanar with a backside resistor wire. In this way the resistor wire and the fuse wire may be formed in the same or substantially the same fabrication processes (e.g., a single etching mask may be used to form the resistor wire and the fuse wire) which may ease semiconductor IC device fabrication complexities.

In another embodiment, a semiconductor integrated circuit (IC) device method is presented. The method includes programming a fuse structure that includes a fuse wire and a deep via contact. The deep via contact is connected to the fuse wire and to a frontside back end of the line (BEOL) network. The fuse wire is connected to a backside contact. The backside contact is connected to a transistor and to a backside BEOL network. The method further includes, as a result of programming the fuse structure, preventing current flow between the frontside BEOL network and a backside BEOL network through the fuse wire. By associating the fuse structure with the backside BEOL network, the presented semiconductor IC device may be further scaled (i.e., shrunk is size) and/or may have reduced signal and/or power wiring routing complexities therein. Further, by placing the fuse wire between the FEOL microdevice and the backside BEOL network, the fuse wire may be located relatively closer to the FEOL microdevice and may require relatively lower (e.g., three to six times lower) programming current compared to known eFUSE placement schemes.

In an example, the fuse wire is between the deep via contact and the backside BEOL network. As such, the fuse wire may be located on the backside of the semiconductor IC device between a front end of the line device and the backside BEOL network, which may reduce signal or wiring routing complexities in the semiconductor IC device.

In an example, a top surface of the fuse wire is connected to a bottom surface of the deep via contact. As such, the fuse wire may be located on the backside of the semiconductor IC device and upon the deep via contact, which may reduce signal or wiring routing complexities in the semiconductor IC device.

In an example, a side surface of the fuse wire is connected to a sidewall of the backside contact. As such, the fuse wire may be located on the backside of the semiconductor IC device above the backside BEOL network and vertically inset with respect to the backside contact, which may reduce signal or wiring routing complexities in the semiconductor IC device.

In an example, a top surface of the backside contact is connected to a source/drain (S/D) region of the transistor. In this way, the backside contact may serve as a terminal to the S/D of the transistor, to the backside BEOL network, and to the fuse wire, which may reduce signal or wiring routing complexities in the semiconductor IC device.

In yet another embodiment, a semiconductor integrated circuit (IC) device method is presented. The method includes programming a fuse structure that includes a fuse wire and a deep via contact. The deep via contact is connected to the fuse wire and to a frontside back end of the line (BEOL) network. The fuse wire is connected to a backside contact. The backside contact is connected to a transistor and to a backside BEOL network. The method further includes, because of programming the fuse structure, preventing the backside contact from routing current through the transistor and the backside contact from routing current between the frontside BEOL network and the backside BEOL network by way of the fuse wire. By associating the fuse structure with the backside BEOL network, the presented semiconductor IC device may be further scaled (i.e., shrunk is size) and/or may have reduced signal and/or power wiring routing complexities therein. Further, by placing the fuse wire between the FEOL microdevice and the backside BEOL network, the fuse wire may be located relatively closer to the FEOL microdevice and may require relatively lower (e.g., three to six times lower) programming current compared to known eFUSE placement schemes.

In an example, the fuse wire is between the deep via contact and the backside BEOL network. As such, the fuse wire may be located on the backside of the semiconductor IC device between a front end of the line device and the backside BEOL network, which may reduce signal or wiring routing complexities in the semiconductor IC device.

In an example, a top surface of the fuse wire is connected to a bottom surface of the deep via contact. As such, the fuse wire may be located on the backside of the semiconductor IC device and upon the deep via contact, which may reduce signal or wiring routing complexities in the semiconductor IC device.

In an example, a side surface of the fuse wire is connected to a sidewall of the backside contact. As such, the fuse wire may be located on the backside of the semiconductor IC device above the backside BEOL network and vertically inset with respect to the backside contact, which may reduce signal or wiring routing complexities in the semiconductor IC device.

The above summary is not intended to describe each illustrated embodiment or every implementation or example of the present disclosure.

### BRIEF DESCRIPTION OF THE DRAWINGS

The drawings included in the disclosure are incorporated into, and form part of, the specification. They illustrate embodiments of the present disclosure and, along with the description, explain the principles of the disclosure. The drawings are only illustrative of certain embodiments and do not limit the disclosure.

FIG. 1A through FIG. 1C depicts a semiconductor IC device that includes a fuse structure that utilizes a backside contact a non-programmed fuse structure state and programmed fuse structure states, according to one or more embodiments of the disclosure.

FIG. 2 through FIG. 20 depict various fabrication structure views of an exemplary semiconductor IC device that includes a fuse structure that utilizes a backside contact, according to one or more embodiments of the disclosure.

FIG. 21 depicts a method of fabricating a semiconductor IC device that includes a fuse structure that utilizes a backside contact, according to one or more embodiments of the disclosure.

### DETAILED DESCRIPTION

The present disclosure describes an illustrative semiconductor IC device that includes at least one backside contact associated with one or more front end of line (FEOL) microdevice(s), such as a GAA transistor. The backside contact is also utilized by a fuse structure. In a non-programmed state, the backside contact is utilized as a terminal for routing current for FEOL microdevice(s) operation(s) and as a terminal for routing current between a frontside back end of line (BEOL) network and a backside BEOL network. For example, when the FEOL microdevice is transistor, in the non-programmed state, the backside contact is the structure that provides electrical current that flows through the channel, into and/or out of the transistor (e.g., source or drain of the transistor). In a first fuse structure programmed state, an open circuit is created that prevents the routing of current between the frontside BEOL network and the backside BEOL network through a fuse wire of the fuse structure but allows the routing of current for FEOL microdevice(s) operation(s). In a second fuse structure programmed state, an open circuit is created within the backside contact that prevents both the routing of current between the frontside BEOL network and the backside BEOL network by way of the fuse structure and the routing of current for FEOL microdevice(s) operation(s).

There are many different types of transistors, such as but not limited to FinFETs, GAA FETs, fork sheet FETs, and the like. Though illustrative GAA FETs are depicted in the drawings, embodiments of the present disclosure should not be limited thereto and may be applied to other transistors.

Conventional transistors, such semiconductor IC devices, or the like, incorporate planar field effect transistors (FETs) in which current flows through a semiconducting channel between a source and a drain, in response to a voltage applied to a control gate. The semiconductor industry strives to obey Moore's law, which holds that each successive generation of integrated circuit devices shrinks to half its size and operates twice as fast. As device dimensions have shrunk, however, conventional silicon device geometries and materials have had trouble maintaining switching speeds without incurring failures such as, for example, leaking current from the device into the semiconductor substrate. Several new technologies emerged that allowed chip designers to continue shrinking transistor sizes. A FET generally is a transistor in which output current, i.e., source-drain current, is controlled by a voltage applied to an associated gate. A FET typically has three terminals, i.e., a gate structure, a source region, and a drain region. A gate structure is a structure used to control output current (i.e., flow of carriers in the channel) of a semiconducting device through electrical or magnetic fields. A channel is the region of the FET underlying the gate structure and between the source and drain of the semiconductor IC device that becomes conductive when the semiconductor device is turned on. The source is a doped region in the semiconductor IC device, in which majority carriers are flowing into the channel. A drain is a doped region in the semiconductor IC device located at the end of the channel, in which carriers are flowing out of the transistor through the drain.

One technology change modified the structure of the FET from a planar device to a three-dimensional device in which the semiconducting channel was replaced by a fin that extends out from the plane of the substrate. In such a device, commonly referred to as a FinFET, the control gate wraps around three sides of the fin to influence current flow from three surfaces instead of one. The improved control achieved with a 3D design results in faster switching performance and reduced current leakage. Building taller devices has also permitted increasing the device density within the same footprint that had previously been occupied by a planar FET.

The FinFET concept was further extended by developing a gate all-around FET, or GAA FET, in which the gate fully wraps around one or more channels for maximum control of the current flow therein. In the GAA FET, the channels can take the form of nanolayers, nanosheets, or the like, that are isolated from the substrate. In the GAA FET, channel surfaces are in respective contact with the source and drain and other respective channel surfaces are in contact with and surrounded by the gate.

The flowcharts and cross-sectional diagrams in the drawings illustrate a method of fabricating semiconductor IC device, such as a processor, FPGA, memory module, or the like. In some alternative implementations, the fabrication steps may occur in a different order that that which is noted in the drawings, and certain additional fabrication steps may be implemented between the steps noted in the drawings. Moreover, any of the layered structures depicted in the drawings may contain multiple sublayers.

Various embodiments of the present disclosure are described herein with reference to the related drawings. Alternative embodiments can be devised without departing from the scope of the present disclosure. It is noted that various connections and positional relationships (e.g., over, below, adjacent, etc.) are set forth between elements in the following description and in the drawings. These connections and/or positional relationships, unless specified otherwise, can be direct or indirect, and the present disclosure is not intended to be limiting in this respect. Accordingly, a coupling of entities can refer to either a direct or an indirect coupling, and a positional relationship between entities can be a direct or indirect positional relationship. As an example of an indirect positional relationship, references in the present description to forming layer “A” over layer “B” include situations in which one or more intermediate layers (e.g., layer “C”) is between layer “A” and layer “B” as long as the relevant characteristics and functionalities of layer “A” and layer “B” are not substantially changed by the intermediate layer(s).

The following definitions and abbreviations are to be used for the interpretation of the claims and the specification. As used herein, the terms “comprises,” “comprising,” “includes,” “including,” “has,” “having,” “contains” or “containing,” or any other variation thereof, are intended to cover a non-exclusive inclusion. For example, a composition, a mixture, process, method, article, or apparatus that comprises a list of elements is not necessarily limited to only those elements but can include other elements not expressly listed or inherent to such composition, mixture, process, method, article, or apparatus.

For purposes of the description hereinafter, the terms “upper,” “lower,” “right,” “left,” “vertical,” “horizontal,” “top,” “bottom,” and derivatives thereof shall relate to the depicted structure(s) as oriented. The terms “overlying,” “atop,” “on top,” “positioned on” or “positioned atop” mean that a first element, such as a first structure, is present on a second element, such as a second structure, wherein intervening elements such as an interface structure can be present between the first element and the second element. The term “direct contact” means that a first element, such as a first structure, and a second element, such as a second structure, are connected without any intermediary conducting, insulating or semiconductor layers at the interface of the two elements.

The terms “about,” “substantially,” “approximately,” and variations thereof, are intended to include the degree of error associated with measurement of the particular quantity based upon the equipment available at the time of filing the application. For example, substantial coplanarity between various materials can include an appropriate manufacturing tolerance of ±8%, ±5%, ±2%, or the like, difference between the coplanar materials.

As used herein, the term “coplanar” refers to two surfaces that lie in a common plane. In other words, two surfaces are coplanar if there exists a geometric plane that contains all of the points of both of the surfaces. Accordingly, two surfaces may be referred to as substantially coplanar despite deviations from coplanarity on an atomic scale, so long as those deviations do not impact the desired result of the coplanarity.

As used herein, the terms “selective” or “selectively” in reference to a material removal or etch process denote that the rate of material removal for a first material is greater than the rate of removal for at least another material of the structure to which the material removal process is applied. For example, in certain embodiments, a selective etch may include an etch chemistry that removes a first material selectively to a second material by a ratio of 2:1 or greater, e.g., 5:1, 10:1 or 20:1.

For the sake of brevity, conventional techniques related to semiconductor IC device fabrication may or may not be described in detail herein. Moreover, the various tasks and process steps described herein can be incorporated into a more comprehensive procedure or process having additional steps or functionality not described in detail herein. Various steps in the manufacture of semiconductor devices are well known and so, in the interest of brevity, many conventional steps will only be mentioned briefly herein or will be omitted entirely without providing the well-known process details.

In general, the various processes used to form a semiconductor IC device that may be packaged into an IC package fall into four general categories, namely, film deposition, removal/etching, semiconductor doping and patterning/lithography. Deposition is any process that grows, coats, or otherwise transfers a material onto the wafer. Available technologies include physical vapor deposition (PVD), chemical vapor deposition (CVD), electrochemical deposition (ECD), molecular beam epitaxy (MBE) and more recently, atomic layer deposition (ALD) among others. Removal/etching is any process that removes material from the wafer. Examples include etch processes (either wet or dry), and chemical-mechanical planarization (CMP), and the like. Semiconductor doping is the modification of electrical properties by doping, for example, transistor sources and drains, generally by diffusion and/or by ion implantation. These doping processes are followed by furnace annealing or by rapid thermal annealing (RTA). Annealing serves to activate the implanted dopants. Films of both conductors (e.g., poly-silicon, aluminum, copper, etc.) and insulators (e.g., various forms of silicon dioxide, silicon nitride, etc.) are used to connect and isolate transistors and their components. Selective doping of various regions of the semiconductor substrate allows the conductivity of the substrate to be changed with the application of voltage. By creating structures of these various components, millions of transistors can be built and wired together to form the complex circuitry of a modern microelectronic device. Semiconductor lithography is the formation of three-dimensional relief images or patterns on the semiconductor substrate for subsequent transfer of the pattern to the substrate. In semiconductor lithography, the patterns are formed by a light sensitive polymer called a photo-resist. To build the complex structures that make up a transistor and the many wires that connect the millions of transistors of a circuit, lithography and etch pattern transfer steps are repeated multiple times. Each pattern being printed on the wafer is aligned to the previously formed patterns and slowly the conductors, insulators and selectively doped regions are built up to form the final device.

Turning now to an overview of technologies that are more specifically relevant to aspects of the present disclosure, a metal-oxide-semiconductor field-effect transistor (MOSFET) may be used for amplifying or switching electronic signals. The MOSFET has a source electrode, a drain electrode, and a metal oxide gate electrode. The metal gate portion of the metal oxide gate electrode is electrically insulated from the main semiconductor n-channel or p-channel by a thin layer of insulating material, for example, silicon dioxide or glass, which makes the input resistance of the MOSFET relatively high. The gate voltage controls whether the current path from the source to the drain is an open circuit (“off”) or a resistive path (“on”). N-type field effect transistors (nFET) and p-type field effect transistors (pFET) are two types of complementary MOSFETs. The nFET includes n-doped source and drain junctions and uses electrons as the current carriers. The pFET includes p-doped source and drain junctions and uses holes as the current carriers. Complementary metal oxide semiconductor (CMOS) is a technology that uses complementary and symmetrical pairs of p-type and n-type MOSFETs to implement logic functions. As mentioned above, hole mobility on the pFET may have an impact on overall device performance.

The wafer footprint of an FET is related to the electrical conductivity of the channel material. If the channel material has a relatively high conductivity, the FET can be made with a correspondingly smaller wafer footprint. A method of increasing channel conductivity and decreasing FET size is to form the channel as a nanostructure, such as a nano wire, nano ribbon, nanolayer, nanosheet, or the like, hereinafter referred to as a nanolayer. For example, a GAA FET provides a relatively small FET footprint by forming the channel region as a series of vertically stacked nanolayers. In a GAA configuration, a GAA FET includes a source region, a drain region and vertically stacked nanolayer channels between the source and drain regions. These devices typically include one or more suspended nanolayers that serve as the channel. A gate surrounds the stacked nanolayers and regulates electron flow through the nanolayers between the source and drain regions. GAA FETs may be fabricated by forming alternating layers of active nanolayers and sacrificial nanolayers. The sacrificial nanolayers are released from the active nanolayers before the FET device is finalized. For n-type FETs, the active nanolayers are typically silicon (Si) and the sacrificial nanolayers are typically silicon germanium (SiGe). For p-type FETs, the active nanolayers can be SiGe and the sacrificial nanolayers can be Si. In some implementations, the active nanolayers of a p-type FET can be SiGe or Si, and the sacrificial nanolayers can be Si or SiGe. Forming the nanolayers from alternating layers of active nanolayers formed from a first type of semiconductor material (e.g., Si for n-type FETs, and SiGe for p-type FETs) and sacrificial nanolayers formed from a second type of semiconductor material (e.g., SiGe for n-type FETs, and Si for p-type FETs) may provide for superior channel electrostatics control, which is necessary for continuously scaling gate lengths.

For some transistors, integration of the transistors with a backside back end of line (BEOL) network is one of the key challenges to providing increasing packaged IC device densities and performance increases. By incorporating a BEOL network into the semiconductor IC device, there may be a logical and/or functional separation between electrical signal routing and electrical power routing through the semiconductor IC device which may ease routing congestion in some applications. Currently, there is a need to incorporate fuse structures within the backside fabrication stages of the semiconductor IC device. Specifically, there is a need to incorporate fuse structures within the backside fabrication stages, without significant additional fabrication stages and costs associated therewith (e.g., without additional mask and associated lithography stages).

Therefore, the embodiments of the present disclosure provide a semiconductor IC device that includes at least one backside contact associated with at least one FEOL microdevice, such as a transistor, diode, memory cell, or the like, associated with a backside BEOL network, and associated with a fuse structure. The backside contact and fuse structure are fabricated within the backside fabrication stages of the semiconductor IC device, without significant additional fabrication stages and costs associated therewith. For example, the fuse structure includes a backside fuse wire that is connected to the backside contact and to a deep via which is connected to a frontside BEOL network. The backside fuse wire may be fabricated along with other backside wires within the backside BEOL network, and additional or specific mask and lithography stages to fabricate the backside fuse wire are not necessarily needed.

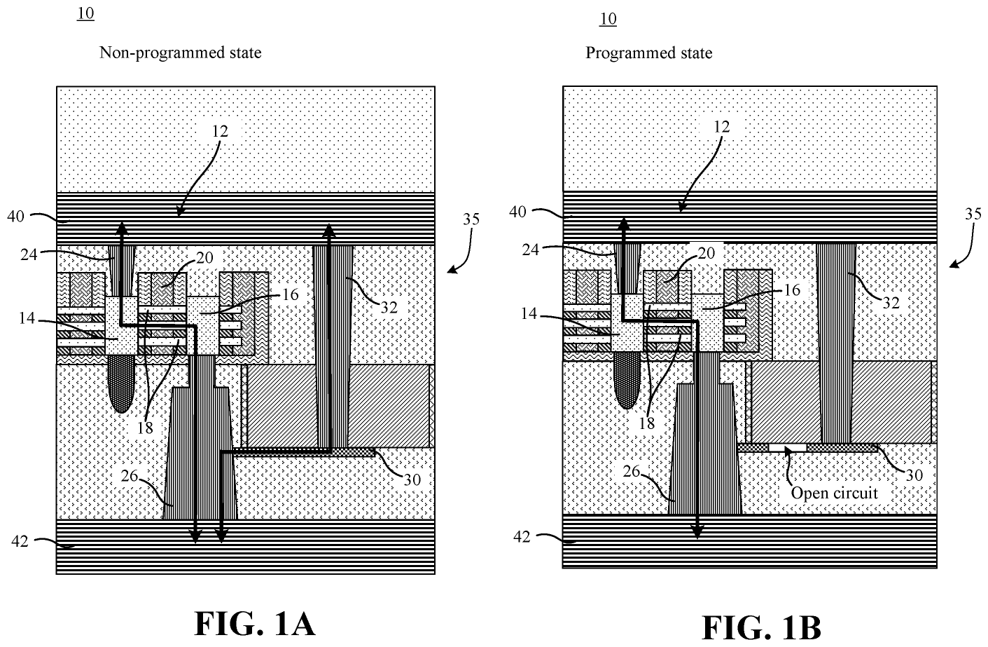

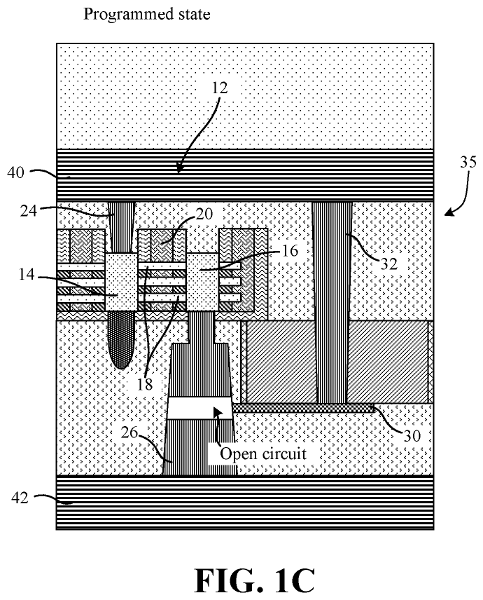

Referring now to FIG. 1A, which depicts a cross-sectional view of a semiconductor IC device 10 that includes a fuse structure 35 is a non-programmed state. Semiconductor IC device 10 further includes a backside contact 26 connected to a transistor 12, connected to a backside BEOL network 42, and connected to a fuse structure 35. Transistor 12 may include a source/drain (S/D) region 14, a S/D region 16, one or more channels 18, and a gate 20. S/D region 14 may be the source of transistor 12 while the S/D region 16 may be the drain of the transistor, or vice versa. The S/D region 14 is connected to a frontside BEOL 40 by a frontside contact 24. The fuse structure 35 includes a fuse wire 30 and a deep via contact 32. The fuse wire 30 is located vertically between the transistor 12 and the backside BEOL network 42 and is connected to the backside contact 26 and to the deep via contact 32. The deep via contact is also connected to the frontside BEOL network 40.

In the non-programmed state of the fuse structure 35, the backside contact 26 may be utilized as a terminal for routing current for transistor 12 operation(s). For example, when a voltage that is greater than the threshold voltage of the transistor 12 is applied to the gate 20, electrical current flows through the one or more channels 18, between the S/D region 14 and the S/D region 16. In other words, in the non-programmed state of the fuse structure 35, when transistor 12 is on, current flows through the transistor 12 by way of the backside contact 26.

Also, in the non-programmed state of the fuse structure 35, the backside contact 26 may be utilized as a terminal for routing current between frontside BEOL network 40 and backside BEOL network 42. For example, the backside contact 26, the fuse wire 30, and the deep via contact 32 provides a current path between frontside BEOL network 40 and backside BEOL network 42.

To program the fuse structure 35, an adequately high voltage (i.e., programming voltage) is applied to the deep via contact 32 that causes an open circuit failure within the fuse wire 30 (as depicted in FIG. 1B) or within the backside contact 26 (as depicted in FIG. 1C).

Referring now to FIG. 1B, which depicts a cross-sectional view of the semiconductor IC device 10 and the fuse structure 35 is a first non-programmed state. In the first programmed state of the fuse structure 35, an open circuit is created that prevents current flow between frontside BEOL network 40 and backside BEOL network 42 by way of the fuse structure 35. In the first programmed state of the fuse structure 35, the open circuit failure (i.e., absence of conductive material) occurs within the fuse wire 30 and prevents the routing of current between the frontside BEOL network 40 and the backside BEOL network 42 by way of the fuse structure 35 but allows the routing of current between the frontside BEOL network 40 and the backside BEOL network 42 for transistor 12 operation(s). Consequently, programming of the fuse structure 35 and the resulting open circuit failure within the fuse wire 30, may prevent functionality or operations of the semiconductor IC device 100 that are associated with current flow through the fuse structure 35.

Referring now to FIG. 1C, which depicts a cross-sectional view of the semiconductor IC device 10 and the fuse structure 35 is a second non-programmed state. In the second programmed state of the fuse structure 35, an open circuit is created within the backside contact 26 that prevents current flow between the frontside BEOL network 40 and the backside BEOL network 42 by way of the fuse structure 35 and prevents the routing of current between the frontside BEOL network 40 and the backside BEOL network 42 for transistor 12 operation(s). Consequently, the open circuit failure within the backside contact 26, may prevent functionality or operations of the semiconductor IC device 100 that are associated with current flow through the fuse structure 35 and with current flow through transistor 12.

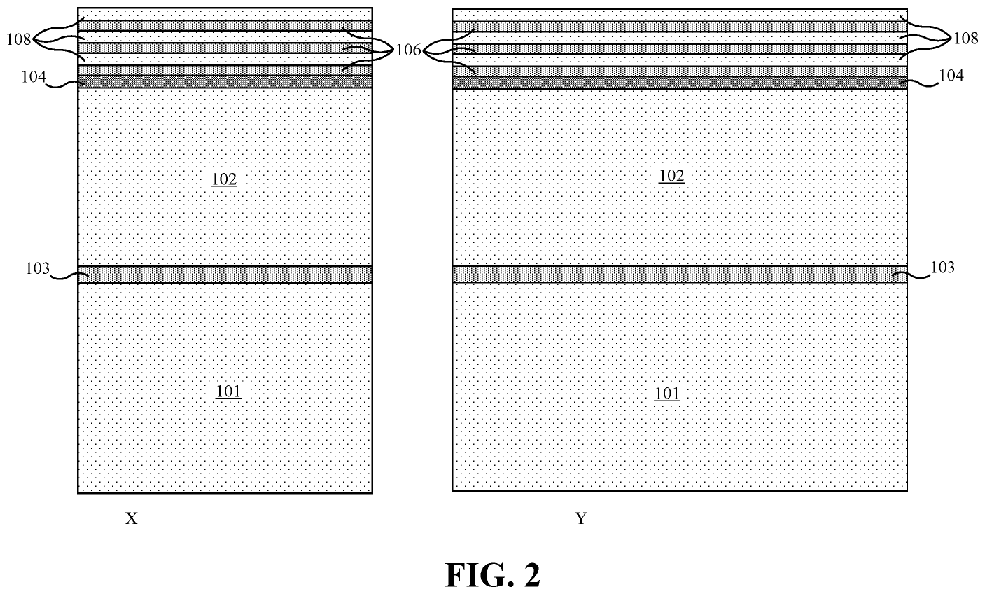

FIG. 2 depicts a cross-sectional view of a semiconductor IC device 100 that includes one or more FEOL microdevices (e.g., one or more GAA FETs) after initial fabrication operations, in accordance with embodiments of the present disclosure. In these initial fabrication stages, nanolayers are formed upon a substrate structure.

The substrate structure may be a bulk-semiconductor substrate. In one example, the bulk-semiconductor substrate may be a silicon-containing material. Illustrative examples of silicon-containing materials suitable for the bulk-semiconductor substrate include, but are not limited to, silicon, silicon germanium, silicon germanium carbide, silicon carbide, polysilicon, epitaxial silicon, amorphous silicon, and multi-layers thereof. Although silicon (Si) is the predominantly used semiconductor material in wafer fabrication, alternative semiconductor materials can be employed, such as, but not limited to, gallium arsenide, gallium nitride, cadmium telluride, zinc selenide, and III-V compound semiconductors and/or II-VI compound semiconductors. III-V compound semiconductors are materials that include at least one element from Group III of the Periodic Table of Elements and at least one element from Group V of the Periodic Table of Elements. II-VI compound semiconductors are materials that include at least one element from Group II of the Periodic Table of Elements and at least one element from Group VI of the Periodic Table of Elements.

In the depicted implementation, the substrate structure includes an upper substrate 102, a lower substrate 101, and an etch stop layer 103 between the upper substrate 102 and the lower substrate 101. The upper substrate 102 and the lower substrate 101 may be comprised of any other suitable material(s) that those listed above and the etch stop layer 103 may be a dielectric material with etch selectivity to one or both of the upper substrate 102 and/or the lower substrate 101. In one example, the etch stop layer 103 may be an oxide and the substrate structure may be referred to as a buried oxide (BOX) substrate. In another example, the lower substrate 101 may be composed of Si. The etch stop layer 103 may be composed of Silicon Germanium (SiGe) and may be epitaxially grown from the top surface of lower substrate 101 and the upper substrate 102 may be composed of Si and may be epitaxially grown from the top surface of etch stop layer 103.

Nanolayers may be formed over the substrate structure by forming a bottom sacrificial nanolayer 104 and by forming a series of alternating sacrificial nanolayers 106 and active nanolayers 108 thereupon. In certain examples, the bottom sacrificial nanolayer 104 is initially formed directly on an upper surface of the substrate structure. In other examples, certain layer(s) may be formed between the upper surface of the substrate structure and the bottom sacrificial nanolayer 104. In an example, the bottom sacrificial nanolayer 104 may be formed by epitaxially growing a SiGe layer with high Ge %, ranging from 50% to 70%. The bottom sacrificial nanolayer 104 generally has etch selectivity relative to the sacrificial nanolayers 106 and active nanolayers 108.

The nanolayers may be further formed by fabricating the alternating series of sacrificial nanolayers 106, such as SiGe sacrificial nanolayers, and active nanolayers 108, such as Si nanolayers, upon the bottom sacrificial nanolayer 104. The sacrificial nanolayers 106 can have Ge % ranging from 20% to 45%. In an implementation, the alternating active sacrificial nanolayer 106 and active nanolayer 108 may be formed by epitaxially growing one layer and then the next until the desired number and desired thicknesses of the layers are achieved. Any number of alternating nanolayers can be provided. Epitaxial materials can be grown from gaseous or liquid precursors. Epitaxial materials can be grown using vapor-phase epitaxy (VPE), molecular-beam epitaxy (MBE), liquid-phase epitaxy (LPE), or other suitable process.

The terms “epitaxial growth and/or deposition” and “epitaxially formed and/or grown” mean the growth of a semiconductor material (crystalline material) on a deposition surface of another semiconductor material (crystalline material), in which the semiconductor material being grown (crystalline overlayer) has substantially the same crystalline characteristics as the semiconductor material of the deposition surface (seed material). In an epitaxial deposition process, the chemical reactants provided by the source gases are controlled and the system parameters are set so that the depositing atoms arrive at the deposition surface of the semiconductor substrate with sufficient energy to move about on the surface such that the depositing atoms orient themselves to the crystal arrangement of the atoms of the deposition surface. Therefore, an epitaxially grown semiconductor material has substantially the same crystalline characteristics as the deposition surface on which the epitaxially grown material is formed. For example, an epitaxially grown semiconductor material deposited on a (100) orientated crystalline surface will take on a (100) orientation. In some embodiments, epitaxial growth and/or deposition processes are selective to forming on semiconductor surfaces, and generally do not deposit material on exposed surfaces, such as silicon dioxide or silicon nitride surfaces.

In the illustrated semiconductor IC device 100, there are a total of three sacrificial nanolayers 106 and three active nanolayers 108. However, it should be appreciated that any suitable number of alternating nanolayers may be formed. Although it is specifically contemplated that the bottom sacrificial nanolayer 104 and the sacrificial nanolayers 106 can be formed from SiGe and that the active nanolayers 108 can be formed from Si, it should be understood that any appropriate materials can be used instead, as long as the semiconductor materials have etch selectivity with respect to one or more of the others, as is consistent with the description of the fabrication stages herein.

Although it is specifically contemplated that the bottom sacrificial nanolayer 104, the sacrificial nanolayers 106, and the active nanolayers 108 are formed by epitaxial growth, such nanolayers can be formed by any appropriate mechanism, such as chemical vapor deposition (CVD), physical vapor deposition (PVD), atomic layer deposition (ALD), or gas cluster ion beam (GCIB) deposition, or the like.

In certain embodiments, the nanolayers have a vertical thickness ranging, for example, from approximately 3 nm to approximately 20 nm. In certain embodiments, the nanolayers have a vertical thickness ranging, for example, from approximately 3 nm to approximately 10 nm. Although the range of 3-20 nm is cited as an example range of thickness of the nanolayers, other thickness of these nanolayers may be used. In certain examples, certain of the nanolayers may have different thicknesses relative to one another. In certain examples, it may be desirable to have a small vertical spacing (VSP) between adjacent active nanolayers 108 to reduce the parasitic capacitance and to improve circuit speed. For example, the VSP (the distance between the bottom surface of a first active nanolayer 108 and the top surface of an adjacent active nanolayer 108) may range from 5 nm to 15 nm. However, the VSP must be of a sufficient value to accommodate the gate that will be formed in the spaces created by later removal of respective portions of the sacrificial nanolayers 106.

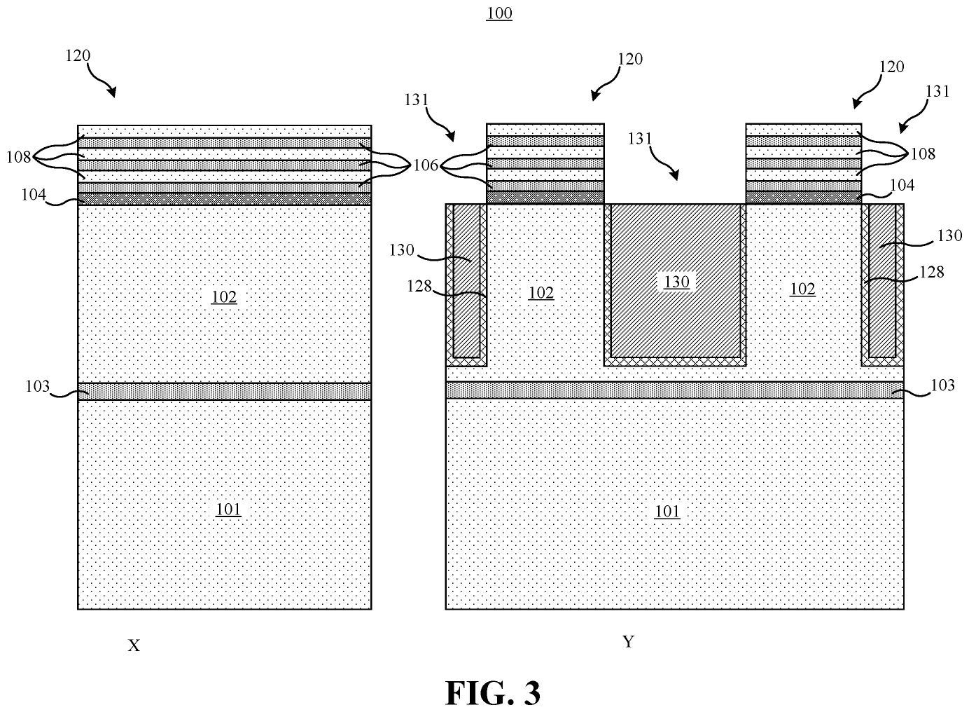

FIG. 3 depicts cross-sectional views of the semiconductor IC device 100 after fabrication operations, in accordance with embodiments of the present disclosure. In the depicted fabrication stages, the nanolayers are patterned into nanolayer stacks 120 and shallow trench isolation (STI) regions are formed.

To form one or more nanolayer stacks 120, a mask layer (not shown) may be formed on the uppermost nanolayer. The mask layer may be comprised of any suitable mask material(s). The mask layer may be patterned and used to perform the nanolayer stack 120 patterning process. In the nanolayer stack 120 patterning process, any suitable material removal process (e.g., reactive ion etching or RIE) may be used to remove portions of the alternating nanolayers down to the level of the substrate structure, or the like. Following the nanolayer stack 120 patterning process, one or more nanolayer stacks 120 are formed. Subsequently, the mask layer may be removed.

The removal of undesired portion(s) of the alternating nanolayers may further remove undesired portions of substrate structure that are adjacent to respective footprints of nanolayer stacks 120 to form STI region openings. The etch may be timed or otherwise controlled to stop the removal of the substrate structure such that the depth or bottom of the one or more STI region openings has a predetermined or desired dimension. For example, the depth or bottom of the one or more STI region openings may be above the etch stop layer 103, as depicted. In some examples, the etch to form the nanolayer stacks 120 may utilize the etch stop layer 103 to stop the etch and form the bottom of the one or more STI region openings.

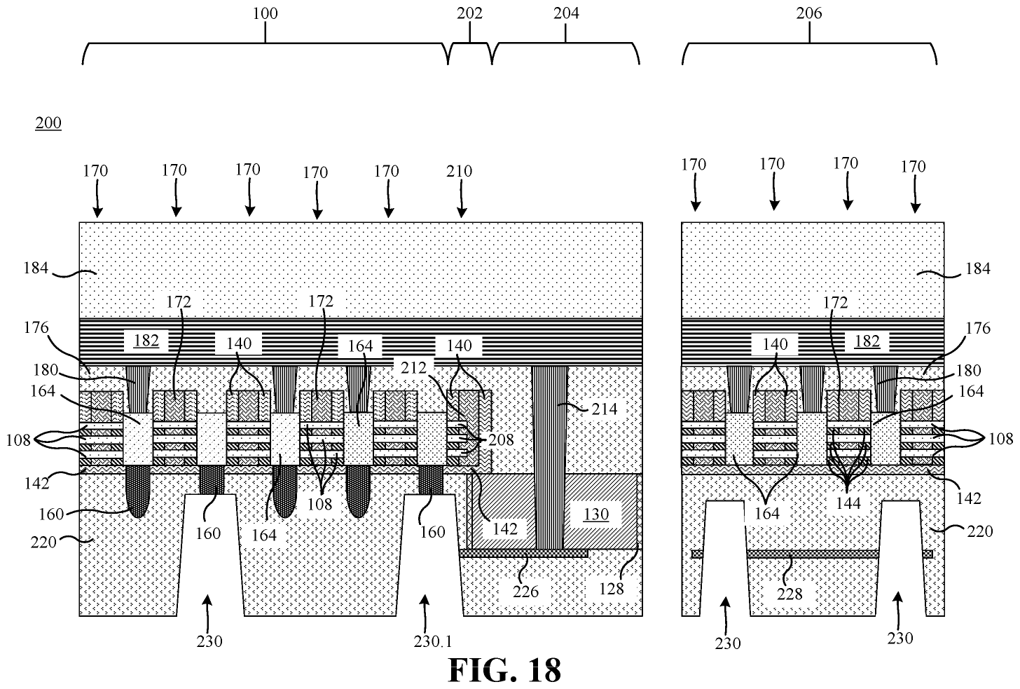

A STI region may be formed upon and/or within the substrate structure within respective STI region openings. For example, one or more STI regions 131 may be formed by depositing electrical dielectric material(s) within respective STI region opening(s) that are adjacent to the one or more nanolayer stacks 120 (e.g., to the front and rear of one or more nanolayer stacks 120), as depicted. For clarity, one or more other STI regions 131 may be formed by depositing electrical dielectric material(s) within respective STI region opening(s) that are adjacent to the one or more nanolayer stacks 120 (e.g., to the side of one or more nanolayer stacks 120), as depicted in FIG. 18.

A top surface of the one or more STI regions 131 may be coplanar with a top surface of the substrate structure. The one or more STI regions 131 may have a volume that sufficiently electrically isolates components or features of neighboring transistors, or the like, and/or may sufficiently electrically isolate neighboring nanolayer stacks 120.

In an example, the STI region(s) 131 may be formed by depositing a STI liner 128 within the STI region openings. Subsequently, STI region(s) 131 may be further formed by depositing STI dielectric material 130 upon the STI liner 128. A etch back, recess, or the like, may occur to remove undesired or over formed STI liner 128 and/or STI dielectric material 130, such that the top surface of the STI region(s) 131 are coplanar with a bottom surface of the bottom sacrificial nanolayer 104. STI liner 128 may be composed of but not limited to a nitride, low-k nitride, or the like. The STI dielectric 130 may be composed of but not limited to an oxide, low-k oxide, or the like.

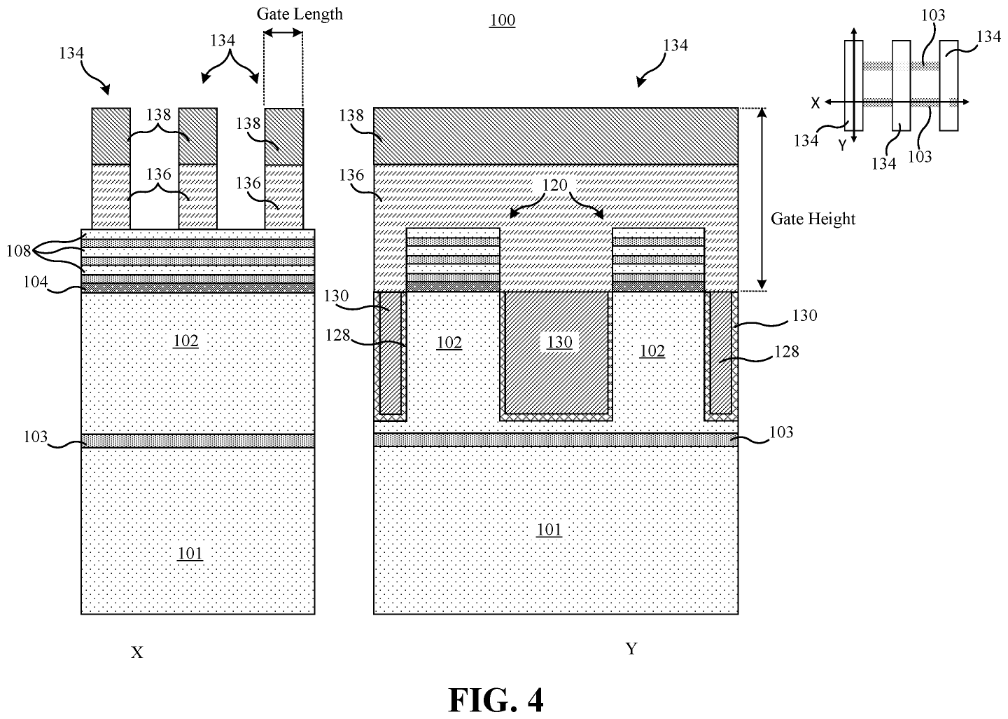

FIG. 4 depicts cross-sectional views of the semiconductor IC device 100 after fabrication operations, in accordance with embodiments of the present disclosure. In the depicted fabrication stages, one or more sacrificial gate structures 134 are formed upon STI regions 131 and upon and around the one or more nanolayer stacks 120. The one or more sacrificial gate structures 134 may include a sacrificial gate liner (not shown), a sacrificial gate 136, and a sacrificial gate cap 138.

The sacrificial gate structures 134 may be formed by initially depositing a sacrificial gate liner layer (e.g., a dielectric, oxide, or the like) upon the one or more STI regions 131 and upon and around the one or more nanolayer stacks 120. The sacrificial gate structures 134 may further be formed by subsequently depositing a sacrificial gate layer (e.g., amorphous silicon, or the like) upon the sacrificial gate liner layer. The thickness of the sacrificial gate layer may be such that the top surface of the sacrificial gate layer is above the top surface of the one or more nanolayer stacks 120. The sacrificial gate structures 134 may further be formed by forming a gate cap layer upon the sacrificial gate layer. The gate cap layer may be formed by depositing a mask material, such as a hard mask material, such as silicon nitride, silicon oxide, combinations thereof, or the like, upon the sacrificial gate layer. The gate cap layer may be composed of one or more layers of masking materials to protect the sacrificial gate layer and/or other underlying materials during subsequent processing of semiconductor IC device 100.

The one or more sacrificial gate structures 134 may further be formed by patterning the gate cap layer, sacrificial gate layer, and sacrificial gate liner by, for example, using lithography and etch processes to remove undesired portions and retain desired portion(s), respectively. The retained desired portion(s) of the gate cap layer, sacrificial gate layer, and sacrificial gate liner may form the sacrificial gate liner (not shown), the sacrificial gate 136, and the sacrificial gate cap 138, respectively, of each of the one or more sacrificial gate structures 134.

One or more sacrificial gate structures 134 can be formed on targeted regions or areas of semiconductor IC device 100 to define the length of one or more GAA FETs and to provide sacrificial material for yielding targeted GAA FET structure(s) in subsequent processing. According to an example, each sacrificial gate structure 134 can have a height of between approximately 50 nm and approximately 200 nm, and a length of between approximately 10 nm and approximately 200 nm.

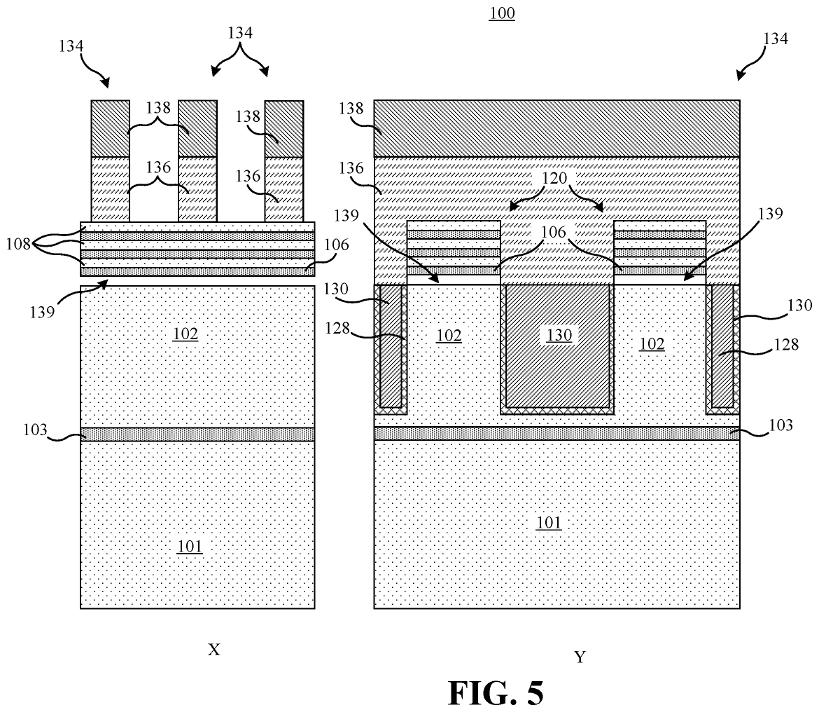

FIG. 5 depicts cross-sectional views of the semiconductor IC device 100 after fabrication operations, in accordance with embodiments of the present disclosure. In the depicted fabrication stages, bottom sacrificial nanolayer 104 is selectively removed.

The bottom sacrificial nanolayer 104 may be selectively removed by a wet etch utilizing an etchant that targets the material if the bottom sacrificial nanolayer 104 selective to the respective material(s) of the sacrificial nanolayers 106, the active nanolayers 108, STI region(s) 131, and/or sacrificial gate structures 134, as appropriate. The etch may be timed or otherwise controlled to effectively remove the bottom sacrificial nanolayer 104 while substantially retaining the sacrificial nanolayers 106, the active nanolayers 108, the STI region(s) 131, and the sacrificial gate structures 134, etc. As depicted, the removal of bottom sacrificial nanolayer 104 forms a bottom dielectric isolation (BDI) cavity 139 between the substrate structure and the bottommost sacrificial nanolayer 106.

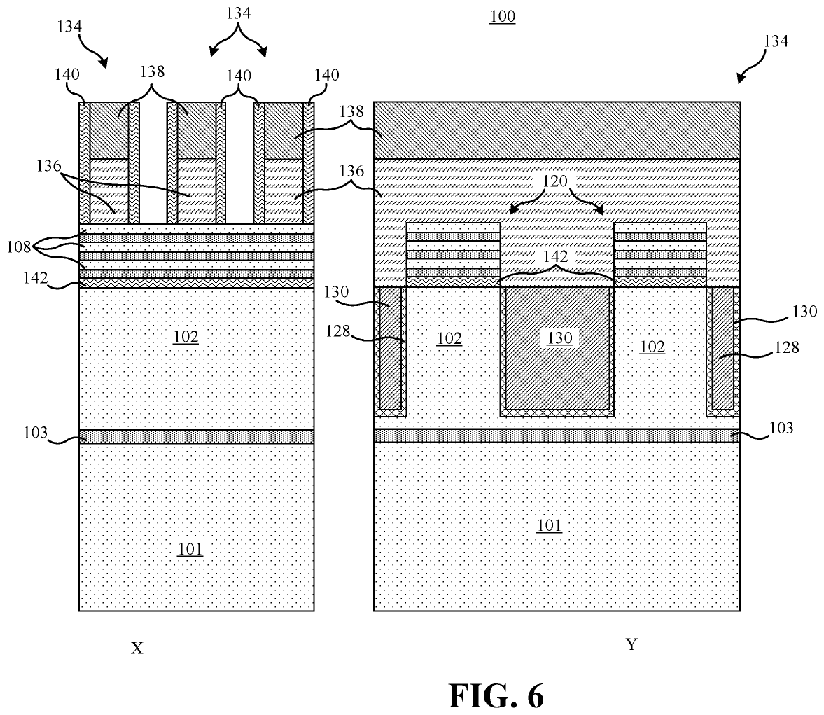

FIG. 6 depicts cross-sectional views of the semiconductor IC device 100 after fabrication operations, in accordance with embodiments of the present disclosure. In the depicted fabrication stages, gate spacers 140 and BDI region 142 are formed.

The BDI region 142 is formed within a respective BDI cavity 139 within the one or more nanolayer stacks 120. The gate spacer(s) 140 are formed upon the sidewall(s) of the sacrificial gate structures 134, upon the STI region(s) 131 (not shown in the depicted cross sections), and around the one or more nanolayer stacks 120.

The BDI region 142 and the gate spacer(s) 140 may be simultaneously formed by a conformal deposition of a dielectric material, such as silicon nitride, SiBCN, SiNC, SiN, SiCO, SiNOC, or a combination thereof, or the like, within the nanolayer cavity 139, upon STI regions 131, upon around the one or more sacrificial gate structures 134, and upon and around the one or more nanolayer stack(s) 120. Subsequently, undesired portions dielectric material may be removed while desired portions the dielectric material may be retained and thereby form the BDI region 142 and the gate spacer(s) 140. The undesired portions of dielectric material may be removed by a directional ion etch, such as a reactive ion etch (RIE). The RIE may remove exposed or unprotected horizontal portions of the dielectric material while retaining protected horizontal portions of the dielectric layer (e.g., the BDI region 142) and vertical portions of the dielectric layer (e.g., the gate spacers 140).

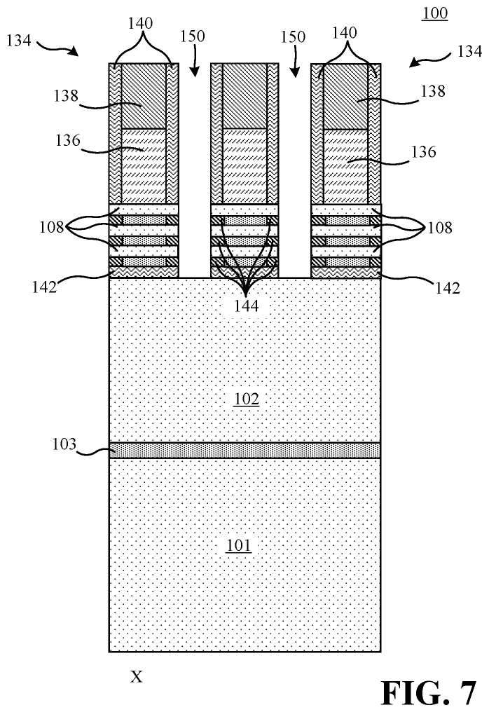

FIG. 7 depicts a cross-sectional view of the semiconductor IC device 100 after fabrication operations, in accordance with embodiments of the present disclosure. In the depicted fabrication stages, source/drain (S/D) recesses 150 are formed within the one or more nanolayer stacks 120 between gate spacers 140 of neighboring sacrificial gate structures 134. In other words, a single nanolayer stack 120 may be separated, by S/D recesses 150, into multiple nanolayer stacks 120 each located underneath a respective sacrificial gate structure 134. Further in the depicted fabrication stages, sacrificial nanolayers 106 are indented and a respective inner spacer 144 is formed in an indent.

The one or more S/D recesses 150 may be formed between adjacent sacrificial gate structures 134 by removing respective portions of the sacrificial nanolayers 106, active nanolayers 108, BDI region 142 that are between gate spacers 140 of adjacent or neighboring sacrificial gate structures 134. The one or more S/D recesses 150 may be formed to a depth to stop at the top surface of the substrate structure (e.g., the top surface of upper substrate 102, or the like), the top surface of STI regions 131, or the like.

The undesired portions of sacrificial nanolayers 106, active nanolayers 108, and BDI region 142 may be removed by etching or other subtractive removal techniques. The top surface of the substrate structure may be used as an etch stop or other etch parameters may be controlled to stop the material removal at the substrate structure. As the gate spacers 140 and the sacrificial gate structures 134 may be utilized to protect the underlying portions of sacrificial nanolayers 106, active nanolayers 108, and BDI region 142, respective sidewalls of the nanolayer stacks 120 may be substantially coplanar with the outer sidewalls of the gate spacers 140 there above.

Further, in the depicted fabrication stages, indents are formed by laterally or horizontally removing respective portions of sacrificial nanolayers 106 within the nanolayer stacks 120. The indents may be formed by a reactive ion etch (RIE) process, which can remove portions of the sacrificial nanolayers 106. The horizontal depth of the indents may be chosen to set a length for the replacement gate structure formed in place of the sacrificial gate structure 134. When the sacrificial nanolayers 106 are composed of SiGe, the directional RIE can use a boron-based chemistry or a chlorine-based chemistry, for example, which recesses or removes the exposed end portions of sacrificial nanolayers 106 (e.g., end portions of sacrificial nanolayers 106 generally below spacer 140) selective to the Si active nanolayers 108. In alternative implementations when sacrificial nanolayers 106 are not SiGe and when active nanolayers 108 are not Si, the directional etch of the sacrificial nanolayers 106 may generally be selective to the active nanolayers 108, gate spacers 140, STI regions 131, and/or substrate structure.

Further, in the depicted fabrication stages, a respective inner spacer 144 is formed within each indent. The one or more inner spacers 144 can be formed by ALD or CVD or any other suitable deposition technique that deposits a dielectric material within the indent(s), thereby forming the inner spacer(s) 144. In some examples, the inner spacer(s) 144 are composed of a low-K dielectric material (a material with a lower dielectric constant relative to SiO₂), SiN, SiO, SiBCN, SiOCN, SiCO, etc. or any other suitable dielectric material. In certain implementations, after the formation of the inner spacer(s) 144, an isotropic etch process is performed to create outer vertical surfaces or sidewalls of the inner spacer(s) 144 that are coplanar with the outer vertical surfaces or sidewalls of the active nanolayers 108, of the gate spacers 140, and/or of the BDI region 142.

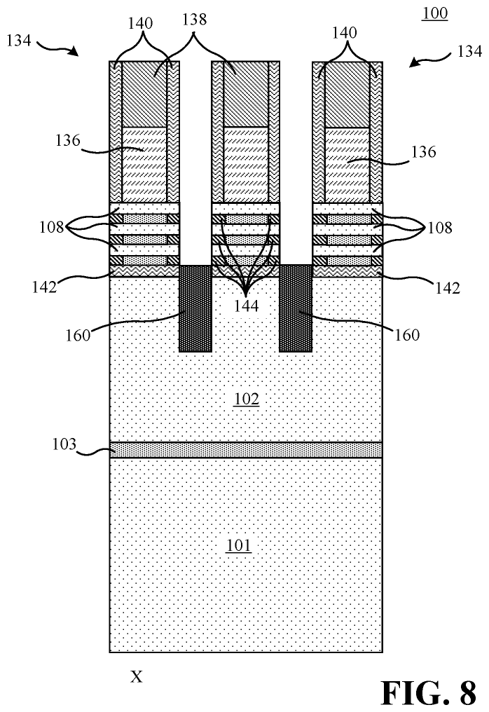

FIG. 8 depicts a cross-sectional view of the semiconductor IC device 100 after fabrication operations, in accordance with embodiments of the present disclosure. In the depicted fabrication stages, one or more backside contact placeholders 160 are formed within the substrate structure in between adjacent sacrificial gate structures 134. In one example, the one or more backside contact placeholders 160 may be formed only in locations in which a backside contact, such as backside contact 26 depicted in FIG. 1, or the like, is to be formed. In an alternative example, a respective backside contact placeholder 160 may be formed in location(s) in which a backside contact is to be formed and in location(s) where a backside contact is not to be formed.

The one or more backside contact placeholders 160 may be formed by initially forming one or more backside contact placeholder cavities within the substrate structure generally in between adjacent sacrificial gate structures 134 and underneath respective one or more S/D recesses 150 (depicted in FIG. 7). For example, the one or more backside contact placeholder(s) cavities may be formed by a subtractive removal technique, such as an etch, that removes associated portion(s) of the upper substrate 102. The etch may be timed or otherwise controlled to stop the removal of the upper substrate 102 such that the depth or bottom of the one or more backside contact placeholder(s) cavities are above the etch stop 103, as depicted.

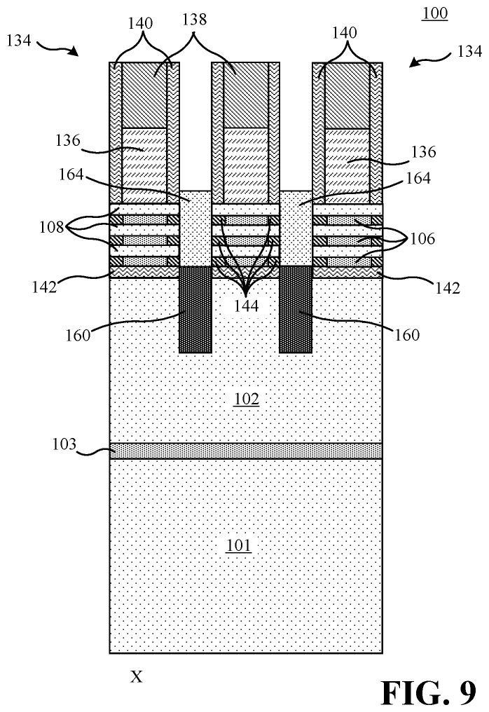

The one or more backside contact placeholders 160 may be further formed by epitaxially growing an epitaxial material from exposed substrate structure surface(s) within the one or more backside contact placeholder(s) cavities. In some embodiments, epitaxial growth and/or deposition processes may be selective to forming on the semiconductor surfaces of the upper substrate 102, and may not deposit material on dielectric surfaces, such as silicon dioxide or silicon nitride surfaces. In some embodiments, the epitaxial growth of the one or more backside contact placeholders 160 may overgrow above the top surface of the substrate structure or above the top surface of BDI region(s) 142. In an example, the epitaxial material of the one or more backside contact placeholders 160 may be chosen to be etch selective to the material of the S/D region(s) 164, exemplarily depicted in FIG. 9, the material of the upper substrate 102, or the like. In another example, an etch stop layer (not shown) is formed upon the top surface of the backside contact placeholders 160. For example, the one or more backside contact placeholders 160 may be SiGe and a Si etch stop layer may be epitaxially grown from the top surface of the SiGe backside contact placeholders 160. Respective top surfaces of the backside contact placeholders 160 (or etch stop layer thereupon) may be substantially horizontal and below the bottom surface of the bottommost active nanolayer 108 (e.g., to enable contact between such active nanolayer 108 and the S/D region 164, as depicted in FIG. 9) and/or substantially coplanar with a respective one or more top surface(s) of BDI region 142.

FIG. 9 depicts a cross-sectional view of the semiconductor IC device 100 after fabrication operations, in accordance with embodiments of the present disclosure. In the depicted fabrication stages, a respective S/D region 164 is formed upon a backside contact placeholder 160 (if present) or upon the substrate structure (if backside contact placeholder 160 is not present) in between adjacent sacrificial gate structures 134.

The S/D region 164 forms either a source or a drain, respectively, of respective GAA FET and is connected to respective a side or end surface of the active nanolayers 108 of a nanolayer stack 120. The S/D region 164 is composed of a semiconductor material and a dopant. As used herein, a “source/drain” region can be a source region or a drain region depending on subsequent wiring and application of voltages during operation of the transistor. The semiconductor material that provides each of the S/D region 164 is composed of one of the semiconductor materials mentioned above for the semiconductor structure. The semiconductor material that provides the S/D region 164 can be compositionally the same, or compositionally different from each active nanolayers 108. The dopant that is present in the S/D region 164 can be either a p-type dopant or an n-type dopant. The term “p-type” refers to the addition of impurities to an intrinsic semiconductor that creates deficiencies of valence electrons. In a silicon-containing semiconductor material, examples of p-type dopants, i.e., impurities, include, but are not limited to, boron, aluminum, gallium, phosphorus and indium. “n-type” refers to the addition of impurities that contributes free electrons to an intrinsic semiconductor. In a silicon containing semiconductor material, examples of n-type dopants, i.e., impurities, include, but are not limited to, antimony, arsenic and phosphorous. In one example, each of the S/D region 164 can have a dopant concentration of from 4×10²⁰ atoms/cm³ to 3×10²¹ atoms/cm³.

The one or more S/D regions 164 may be epitaxially grown or formed. In some examples, the S/D region 164 are formed by in-situ doped epitaxial growth. The use of an in-situ doping process is merely an example. For instance, one may instead employ an ex-situ process to introduce dopants into the source and drains. Other doping techniques can be used to incorporate dopants in the bottom source/drain region. Dopant techniques include but are not limited to, ion implantation, gas phase doping, plasma doping, plasma immersion ion implantation, cluster doping, infusion doping, liquid phase doping, solid phase doping, in-situ epitaxy growth, or any suitable combination of those techniques. In examples, the S/D epitaxial growth conditions that promote in-situ Boron doped SiGe for p-type transistor and phosphorus or arsenic doped silicon or Si:C for n-type transistors.

In some examples, the epitaxial growth that forms the one or more S/D region 164 occurs or is promoted from the top surface of upper substrate 102, from the upper surface of backside contact placeholders 160 (or etch stop layer thereupon), while epitaxial growth is limited or does not occur from neighboring STI regions 131.

In some embodiments, epitaxial growth to form the one or more bottom S/D regions 152 may overgrow above the upper surface of the semiconductor IC device 100 and be subsequently recessed such that the top surface of the S/D region 164 is above the top surface of the topmost active nanolayer 108 within the first series of nanolayers (e.g., to enable contact between such active nanolayer 108 and the S/D region 164).

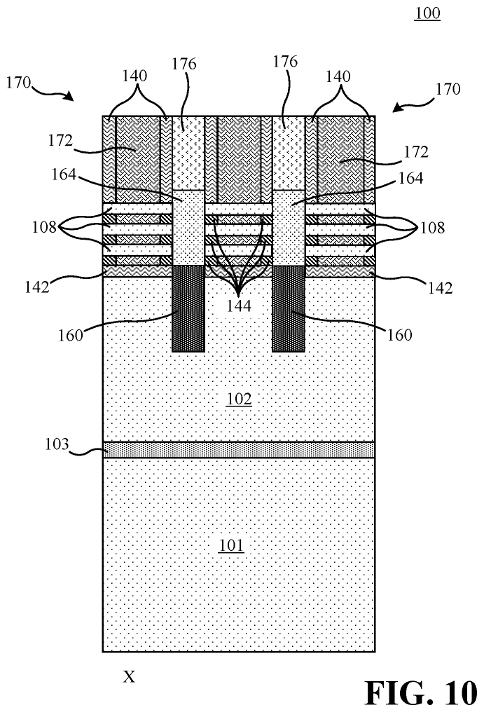

FIG. 10 depicts a cross-sectional view of the semiconductor IC device 100 after fabrication operations, in accordance with embodiments of the present disclosure. In the depicted fabrication stages, an interlayer dielectric (ILD) 176 is formed. For example, ILD 176 may be formed upon the S/D region 164 and upon at least the sidewalls of the gate spacers 140 associated with adjacent sacrificial gate structures 134. Further, in the depicted fabrication stages, the sacrificial gate structures 134 are removed and a replacement gate structure 170 is formed in place thereof.

The ILD 176 may be formed by depositing a blanket dielectric material. The ILD 176 can be any suitable material, such as, for example, porous silicates, carbon doped oxides, silicon dioxides, silicon nitrides, silicon oxynitrides, organic planarization material (OPL), or other dielectric materials. Any known manner of forming the ILD 176 can be utilized. The ILD 176 can be formed using, for example, CVD, PECVD, ALD, flowable CVD, spin-on dielectrics, or PVD.

In an example, the ILD 176 may be formed to a thickness above the top surface of the sacrificial gate structures 134. Subsequently, a planarization process, such as a CMP, may be performed to remove excess ILD 176 material, to remove the sacrificial gate caps 138, and to partially remove the gate spacers 140. The planarization may also partially remove some of the sacrificial gate 136 or may at least expose the sacrificial gate 136 of the sacrificial gate structures 134. The CMP may create a planar or horizontal top surface for the semiconductor IC device 100. In other words, the respective top surfaces of ILD 176, gate spacers 140, sacrificial gates 136 may be coplanar.

Further, in the depicted fabrication stages, the sacrificial gate structures 134 are removed and a replacement gate structure 170 is formed in place thereof. The sacrificial gate structures 134 may be removed by initially removing the sacrificial gate 136 and sacrificial gate oxide by a removal technique, such as one or more series of etches. For example, such removal may be accomplished by a wet chemical etching process in which one or more chemical etchants are used to remove the sacrificial gate 136 and sacrificial gate oxide of the sacrificial gate structures 134. Appropriate etchants may be used that remove the sacrificial gate 136 and/or sacrificial gate oxide selective to the active nanolayers 108, inner spacers 144, gate spacers 140, BDI region 142, STI regions 131, and substrate structure, or the like.

Next, the active nanolayers 108 may be released by removing the sacrificial nanolayers 106. The sacrificial nanolayers 106 may be removed by a removal technique, such as one or more series of etches. For example, the etching can include a wet chemical etching process in which one or more chemical etchants are used to remove the sacrificial nanolayers 106. Appropriate etchants may be used that remove the sacrificial nanolayers 106 selective to the active nanolayers 108, inner spacers 144, inner spacers 145, BDI region 142, gate spacers 140, or the like. After the removal of sacrificial nanolayers 106, there are void spaces above and/or below the active nanolayers 108.

Further, in the depicted fabrication stages, a replacement gate structure 170 is formed in place of the removed sacrificial gate structures 134 around the active nanolayers 108, around the bottom MDI region 129, and upon BDI region 142.

Replacement gate structure(s) 170 may be formed by initially forming an interfacial layer on the gate spacers 140, on the active nanolayers 108, on the BDI region 142, on the inner spacers 144, etc. that are interior to and/or upon the respective surfaces interior to the opening created by the removal of the sacrificial gate structure 134 and releasing of the active nanolayers 108. The interfacial layer can be deposited by any suitable techniques, such as ALD, CVD, PVD, thermal oxidation, combinations thereof, or other suitable techniques.

Replacement gate structure(s) 170 may be further formed by forming a high-k layer to cover the exposed surfaces of the interfacial layer. The high-K layer can be deposited by any suitable techniques, such as ALD, CVD, metal-organic CVD (MOCVD), PVD, thermal oxidation, combinations thereof, or other suitable techniques. A high-K material is a material with a higher dielectric constant than that of SiO₂, and can include e.g., LaO, AlO, ZrO, TiO, Ta₂O₅, Y₂O₃, SrTiO₃(STO), BaTiO₃(BTO), BaZrO, HfZrO, HfLaO, HfSiO, LaSiO, AlSiO, HfTaO, HfTiO, (Ba,Sr)TiO₃(BST), Al₂O₃, Si₃N₄, oxynitrides (SiON), or other suitable materials. The high-K layer can include a single layer or multiple layers, such as metal layer, liner layer, wetting layer, and adhesion layer. In other embodiments, the high-k layer can include, e.g., Ti, Ag, Al, TiAIN, TaC, TaCN, TaSiN, Mn, Zr, TiN, TaN, Ru, Mo, Al, WN, Cu, W, or any suitable materials.

Replacement gate structure(s) 170 may be further formed by depositing a work function (WF) gate upon the high-K layer. The WF gate can be comprised of a conductor or metal, such as, e.g., copper (Cu), cobalt (Co), aluminum (Al), platinum (Pt), gold (Au), tungsten (W), titanium (Ti), nitride (N) or any combination thereof. The metal can be deposited by a suitable deposition process, for example, chemical vapor deposition (CVD), plasma enhanced chemical vapor deposition (PECVD), physical vapor deposition (PVD), plating, thermal or e-beam evaporation, or sputtering. In general, the WF gate sets the threshold voltage (Vt) of the device. The high-K layer may separate the WF gate from the nanolayer channel (i.e., active nanolayer 108). Other metals that may be desired to further fine tune the effective work function (eWF) and/or to achieve a desired resistance value associated with current flow through the gate in the direction parallel to the plane of the nanolayer channel.

The one or more replacement gate structure(s) 170 may be further formed by depositing a conductive fill gate 172 upon the WF gate. The conductive fill gate 172 can be comprised of a conductor material and/or metal, such as but not limited to, e.g., tungsten, aluminum, ruthenium, rhodium, cobalt, copper, tantalum, titanium, carbon nanowire materials including graphene, or the like. The metal can be deposited by a suitable deposition process, for example, chemical vapor deposition (CVD), plasma enhanced chemical vapor deposition (PECVD), physical vapor deposition (PVD), plating, thermal or e-beam evaporation, or sputtering. After the replacement gate structure 170 formation, the top surface of the semiconductor IC device 100 may be planarized by a planarization technique such as a CMP, mechanical grinding process, or the like. After the planarization technique, respective top surfaces of the ILD 176, gate spacers 140, replacement gate structure(s) 170, may be substantially horizontal and/or may be substantially coplanar.

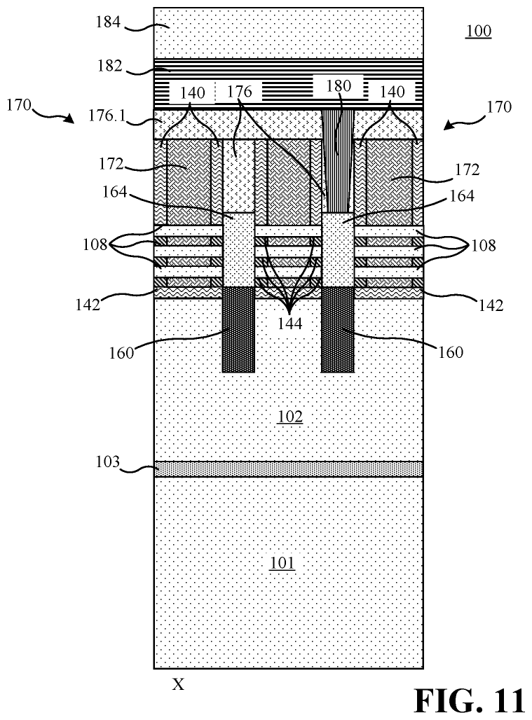

FIG. 11 depicts cross-sectional views of the semiconductor IC device 100 after fabrication operations, in accordance with embodiments of the present disclosure. In the depicted fabrication stages, ILD 176.1 is formed, one or more frontside contact(s) 180 are formed, a frontside BEOL network 182 is formed, and a carrier wafer 184 is attached.

The ILD 176.1 may be formed upon respective top surfaces of replacement gate structure 170 and ILD 176. The ILD 176.1 may be formed by depositing a dielectric material, such as, for example, porous silicates, carbon doped oxides, silicon dioxides, silicon nitrides, silicon oxynitrides, or other dielectric materials. Any appropriate deposition technique for forming the ILD 176.1 can be utilized. The ILD 176.1 can be formed using, for example, CVD, PECVD, ALD, flowable CVD, spin-on dielectrics, or PVD.

The frontside contact(s) 180 may be formed by patterning respective frontside contact openings within ILD 176.1, ILD 176, or the like, from the frontside (i.e., from above the semiconductor IC device 100, as depicted, downward to respective structures thereof). The frontside contact(s) 180 may be in direct or indirect physical and electrical contact and/or may physically meld with respective material(s) of one or more regions of the semiconductor IC device 100. For example, frontside contact 180 is in direct contact with S/D region 164. Similarly, another frontside contact 180 (not shown) may be in direct contact with replacement gate structure 170.

The frontside contact(s) 180 may be formed by initially forming frontside contact opening(s). The frontside contact opening(s) may be formed by the same or shared lithography and etch process(es), or sequential lithography and etch processes. In such process(es), a mask may be applied and patterned. An opening in the patterned mask may expose the portion of the underlying ILD 176.1 to be removed while other protected portions of semiconductor IC device 100 thereunder may be protected and retained. In such process(es), the dry and wet etching processes can have etching parameters that can be tuned, such as etchants used, etching temperature, etching solution concentration, etching pressure, source power, RF bias voltage, RF bias power, etchant flow rate, to promote desired material removal and desired material retention.

The frontside contact(s) 180 may be further formed by depositing conductive material such as metal into the respective frontside contact opening(s). In an example, frontside contact(s) 180 may be formed by depositing a liner, such as Ni, NiPt or Ti, etc. into the contact opening(s), depositing a metal adhesion liner, such as TIN, TaN, etc. upon the liner, and by depositing a conductive metal fill, such as Al, Ru, W, Co, Cu, etc. upon the metal adhesion liner. Subsequently, a planarization process, such as a CMP process or a mechanical grinding process, may remove excess portions of the conductive barrier layer and the conductive material. Subsequently, the respective top surfaces of frontside contact(s) 180 and ILD 176.1 may be coplanar.

In the semiconductor IC device fabrication industry, there are three sections referred to in a build: front-end-of-line (FEOL), back-end-of-line (BEOL), and the section that connects those two together, the middle-of-line (MOL). The FEOL is made up of the semiconductor devices, e.g., transistors, the BEOL is made up of interconnects and wiring, and the MOL is an interconnect between the FEOL and BEOL that includes material to prevent the diffusion of BEOL metals to FEOL devices. The frontside contact(s) 180 may be a part of the MOL.

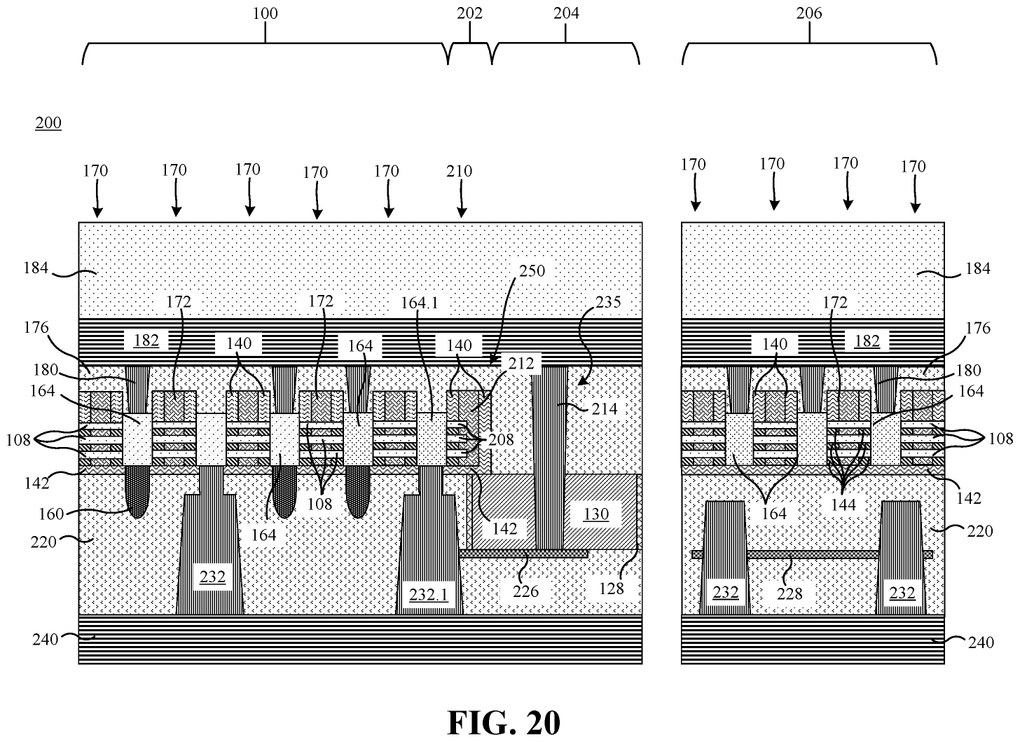

BEOL is the second portion of IC fabrication where the individual devices (e.g., transistors, capacitors, resistors, etc.) become interconnected with wiring on the wafer, e.g., the metallization layer or layers. BEOL includes contacts, insulating layers (dielectrics), metal levels, and bonding sites for chip-to-package connections. In the BEOL, part of the fabrication stage contacts (pads), interconnect wires, vias and dielectric structures are formed. For modern IC processes, more than metal layers may be added in the BEOL. In the present example, there are multiple BEOL levels each on opposites sides of the semiconductor IC device 100. First, a frontside BEOL network 182 is formed on the frontside of the semiconductor device 100. Subsequently, a backside BEOL network 240, as depicted in FIG. 20 is formed.

In the depicted example, the frontside BEOL network 182 is formed over the ILD 176.1 and upon the frontside contact(s) 180. Respective wires within the frontside BEOL network 182 may be electrically connected to the one or more S/D regions 164, one or more replacement gate structure(s) 170 by a respective frontside contact 180. The frontside BEOL network 182 is located directly on the frontside surface of the MOL structure (e.g., ILD 176.1, frontside contacts 180, etc.). The frontside BEOL network 182 can include one or more interconnect dielectric material layers (including one of the dielectric materials mentioned above for the frontside ILD layer 158) and contains frontside metal wires (the metal wires can be composed of any electrically conductive metal or electrically conductive metal alloy) embedded therein. In some embodiments, the frontside metal wires within the frontside BEOL network 182 are composed of Cu. The frontside BEOL network 182 can include “x” numbers of frontside metal levels, wherein “x” is an integer starting from 1. The frontside BEOL network 182 may further contain conductive pads that are connected to one or more of the metal wires and may be used to connect the semiconductor IC device to an external and/or higher-level structure, such as a chip carrier, motherboard, or the like.

The carrier wafer 184 can include one of the semiconductor materials mentioned above for the semiconductor structure. Carrier wafer 184 may be attached to the semiconductor IC device 100 by a wafer-to-wafer bonding technique.

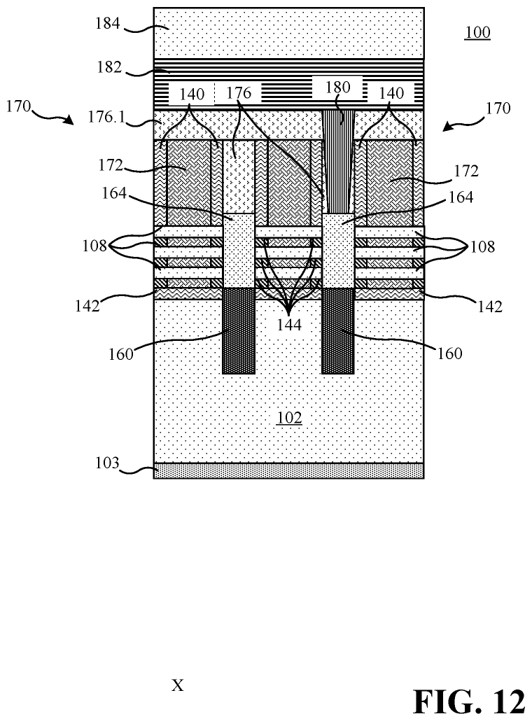

FIG. 12 depicts cross-sectional views of the semiconductor IC device 100 after fabrication operations, in accordance with embodiments of the present disclosure. In the depicted fabrication stages, substrate structure may be recessed. For example, the lower substrate 101 may be removed.

The substrate structure may be recessed by flipping the semiconductor IC device 100 (not shown) and removing the lower substrate 101 using any removal technique, such as a combination of wafer grinding, CMP, dry, and/or wet etch. In the example depicted, lower substrate 101 is removed by an etch that utilizes etch stop layer 103 as the etch stop. In this example, removal of lower substrate 101 exposes the bottom surface of etch stop layer 103.

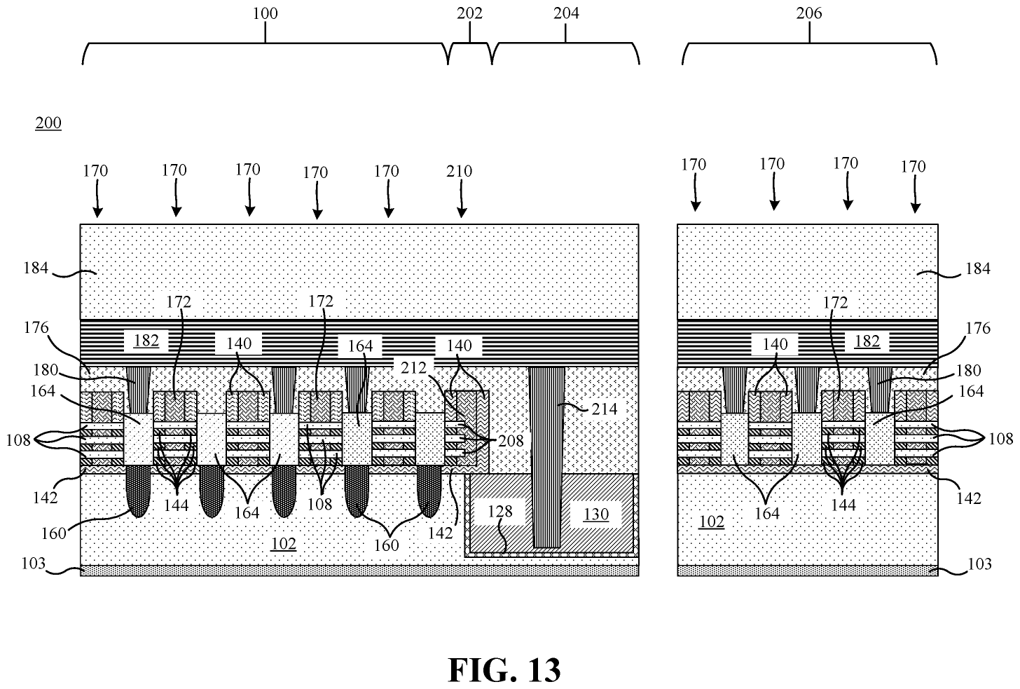

FIG. 13 depict cross-section views of semiconductor IC device 200 that is to include a fuse structure that utilizes a backside contact, according to one or more embodiments of the disclosure. The Semiconductor IC device 200 is depicted at a similar fabrication stage relative to the semiconductor IC device 100 of FIG. 12.

Semiconductor IC device 200 has a semiconductor IC device 100 region in which a semiconductor IC device 100 is formed and a fuse region 204 in which one or more fuse structures are formed. A diffusion break region 202 may be located between semiconductor IC device 100 region and the fuse region 204. Semiconductor IC device 200 may further include a resistor region 206.

Semiconductor IC device 100 region includes semiconductor IC device 100 which has one or more FEOL microdevices, such as GAA FETs, which may be formed by the fabrication operations as described above. Diffusion break region 202 includes a diffusion break gate 210 in which faux channels 208 are tucked within a faux gate 212. The term “faux channel” is defined herein to mean a structure of material that is not used as a channel of a transistor and that at least mirrors a different instance of material (e.g., is the same and/or substantially the same material) that is in a different location that is used as a channel of the associated transistor. Similarly, the term “faux gate region” is defined herein to mean a structure of material that is not used as a gate of a transistor and that structurally (e.g., same dimensions, or the like) and compositionally (e.g., same material, or the like) mirrors a different instance of material that is in a different location that is used as the gate of the associated transistor. In an example, as depicted, the faux channels 208 and the faux gate 212 may be effectively formed due to a lack of a S/D region to complete what would otherwise be a function transistor, due to a lack of a contact that connects the region to the BEOL network, due to the channels being inset within the gate and not contacting a S/D region, or the like. Faux channels 208 may be fabricated during the same fabrication stages utilized to fabricate the active nanolayers 108 and faux gate 212 may be fabricated during the same fabrication stages utilized to fabricate the replacement gate structures 170.

Fuse region 204 includes an STI region and deep via contact 214. The deep via contact 214 is formed within the STI region and within the ILD (e.g., 176. 176.1) of the semiconductor IC device. The deep via contact 214 may be formed along with the frontside contacts 180, in MOL fabrication stages. For example, a deep via contact etch (or a series of etches) may form a deep via contact opening within the ILD and within the underlying STI region. Next, conductive material may be formed within the deep via contact opening to form the deep via contact 214. A CMP may planarize the top surface of the semiconductor IC device 200 so that the respective top surfaces of the ILD, the frontside contacts 180, and the deep via contact 214. In this way, the frontside BEOL network 182 may be formed upon the deep via contact 214 as well as the frontside contact(s) 180. For clarity, each of the frontside contacts 180 and the deep via contact 214 may be connected to a respective frontside metal wire within the frontside BEOL network 182.

Resistor region 206 includes one or more FEOL microdevices, such as GAA FETs, which may be formed by the fabrication operations as described above and further is to include one or more backside resistor wire(s), fabricated in subsequent fabrication stages.

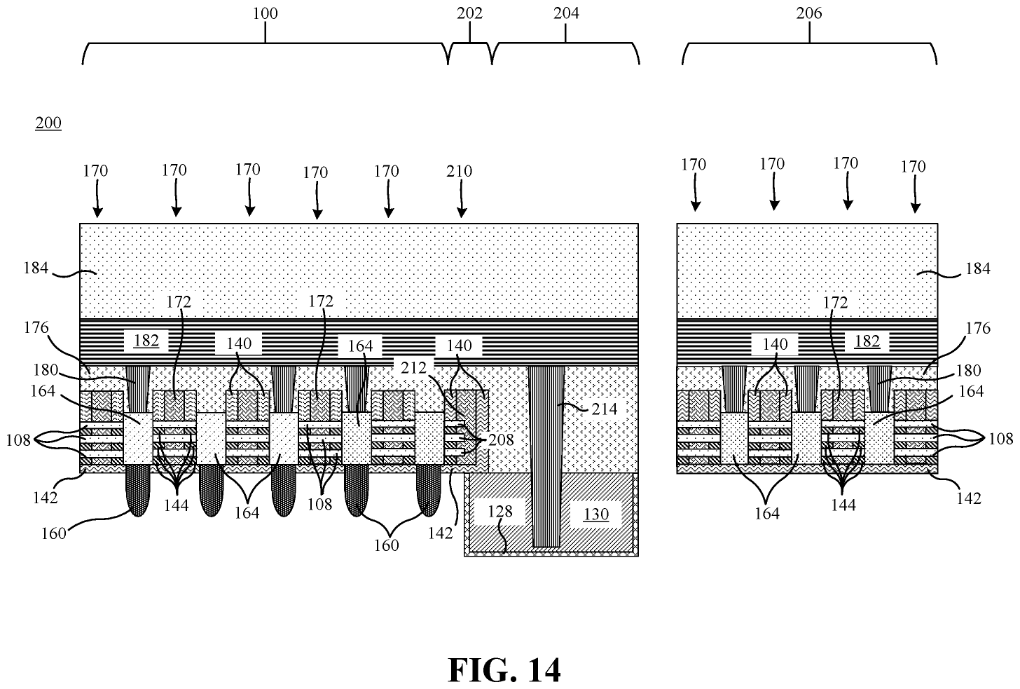

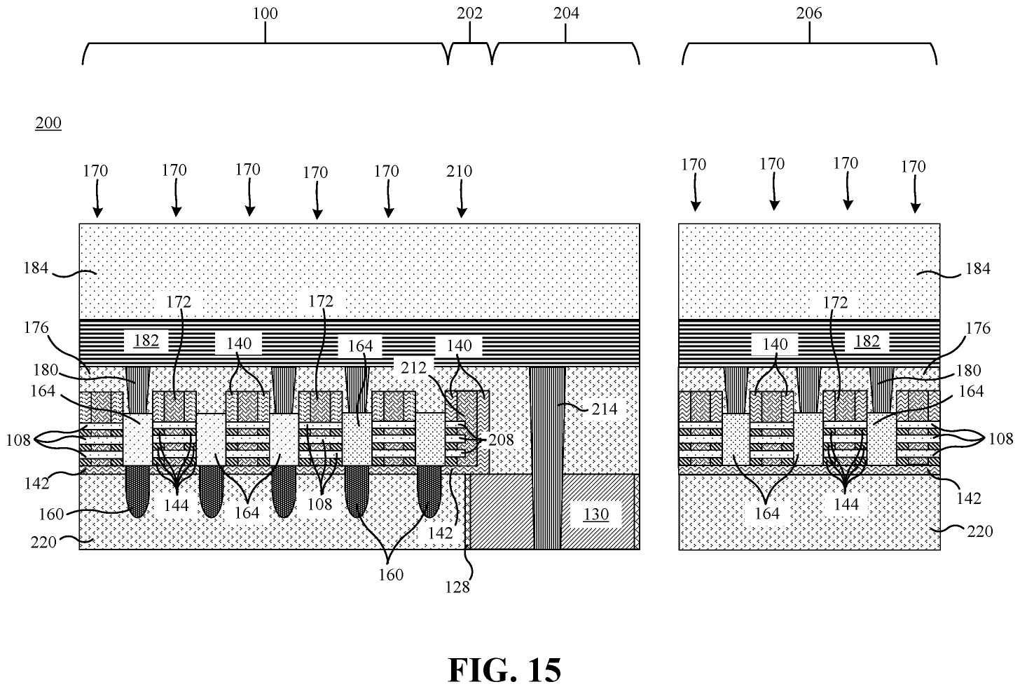

FIG. 14 depicts cross-sectional views of the semiconductor IC device 200 after fabrication operations, in accordance with embodiments of the present disclosure. In the depicted fabrication stages, the remaining substrate structure may be removed. For example, etch stop layer 103 and the upper substrate 102 may be removed.

The etch stop layer 103 may be removed by a subtractive removal technique such as a CMP, dry and/or wet etch. Upon removal of the etch stop layer 103, the bottom surface upper substrate 102 is exposed. The removal of etch stop layer 103 may be selective to the material of upper substrate 102. For example, etch stop layer 103 is removed by an etch that utilizes upper substrate 102 as the etch stop.

Subsequently, the upper substrate 102 is removed by an appropriate substrative removal technique, such as an etch, that removes associated portion(s) of the upper substrate 102. The etch may be timed or otherwise controlled to remove the material of substrate 105 and retain or otherwise expose the STI regions, retain and partially expose one or more backside contact placeholders 169, and retain and expose at least a portion of the BDI region 142.

FIG. 15 depicts cross-sectional views of semiconductor IC device 200 shown after exemplary fabrication operation(s), in accordance with one or more embodiments. In the depicted fabrication stage, backside ILD 220 is formed upon the exposed backside of the semiconductor IC device 200 and a bottom surface (as depicted) of deep via contact 214 is exposed.

The backside ILD 220 may be formed upon the bottom surfaces (as depicted) of the STI regions, upon the bottom surfaces (as depicted) one or more backside contact placeholders 160, and upon the bottom surfaces (as depicted) of the BDI region 142. The backside ILD 220 may be formed by depositing a dielectric material, such as, for example, porous silicates, carbon doped oxides, silicon dioxides, silicon nitrides, silicon oxynitrides, or other dielectric materials. Any appropriate deposition technique for forming the backside ILD 220 can be utilized. The backside ILD 220 can be formed using, for example, CVD, PECVD, ALD, flowable CVD, spin-on dielectrics, or PVD.

In an example, the backside ILD 220 may be formed to a thickness below (as depicted) the bottom surface of the STI regions. Subsequently, a planarization process, such as a CMP, may be performed to remove excess backside ILD 220 material and to partially remove the STI regions so as to expose a bottom surface of the deep via contact 214. The planarization process may not only expose the bottom surface but also remove a portion of the deep via contact 214. The planarization process may create a planar or horizontal bottom surface (as depicted) for the semiconductor IC device 200.

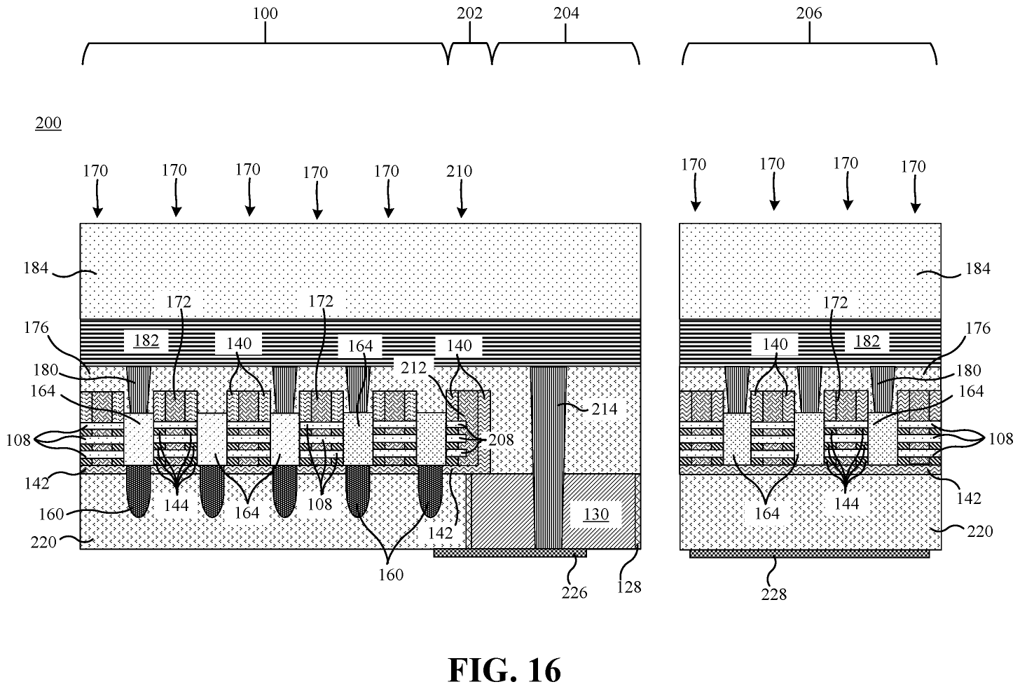

FIG. 16 depicts cross-sectional views of semiconductor IC device 200 shown after exemplary fabrication operation(s), in accordance with one or more embodiments. In the depicted fabrication stage, backside fuse wire 226 and backside wire 228 are formed. The backside fuse wire 226 is formed upon the respective bottom surfaces of the backside ILD 220, STI region, and the deep via contact 214 (as depicted) within semiconductor IC device 100 region, within diffusion break region 202, and within fuse region 204. The backside wire 228 is formed upon the bottom surface (as depicted) of the backside ILD 220 within resistor region 206.

Fusing wire 226 and backside wire 228 are formed of conductive material and may be formed by a deposition process such as CVD, plating, or the like. The fuse wire 226 and backside wire 228 may be formed by the same or shared lithography and etch process(es). In such process(es), a shared mask may be applied and patterned. Backside wire opening(s) in the patterned mask may expose the respective locations upon ILD 220, STI region, and the deep via contact 214 to which the backside wires are to be formed while other protected portions of semiconductor IC device 200 thereunder may be protected from backside wire formation thereupon.

Fusing wire 226 and backside wire 228 may be further formed by depositing conductive material such as metal into the respective backside wire opening(s). In an example, the fuse wire 226 and backside wire 228 may be formed by depositing a conductive metal fill, such as Al, Ru, W, Co, Cu, etc. within the backside wire opening(s). Subsequently, a substrative removal technique, such as an etch or series of etches, may remove excess portions of the conductive material and the shared mask.

Fusing wire 226 is located within semiconductor IC device 100 region, within diffusion break region 202, and within fuse region 204. Fusing wire 226 is further located vertically between the backside BEOL network 240 (show in FIG. 20) and the one or more FEOL microdevices (e.g., one or more GAA FETs). A first end surface of fuse wire 226 may be horizontally inset relative to a predetermined backside contact placeholder 160, as depicted. This predetermined backside contact placeholder 160 is associated with the backside contact that is to be formed and positionally allows for such backside contact to connect with both the fuse wire 226 and the S/D region 164 located there above. A second end surface, distal to the first end surface of the fuse wire 226, is located to allow for the deep via contact 214 to be horizontally inset therewithin, to allow for the entire bottom surface of deep via contact 214 to directly contact the fuse wire 226, or the like.

Backside wire 228 is a wire that X, Y, Z and is located on the backside of the semiconductor IC device 200 not within the backside BEOL network 240, as is depicted in FIG. 20. The geometry (e.g., volume, depicted length, or the like) of conductive material that form backside wire 228 may be chosen to achieve a predetermined resistance therethrough.

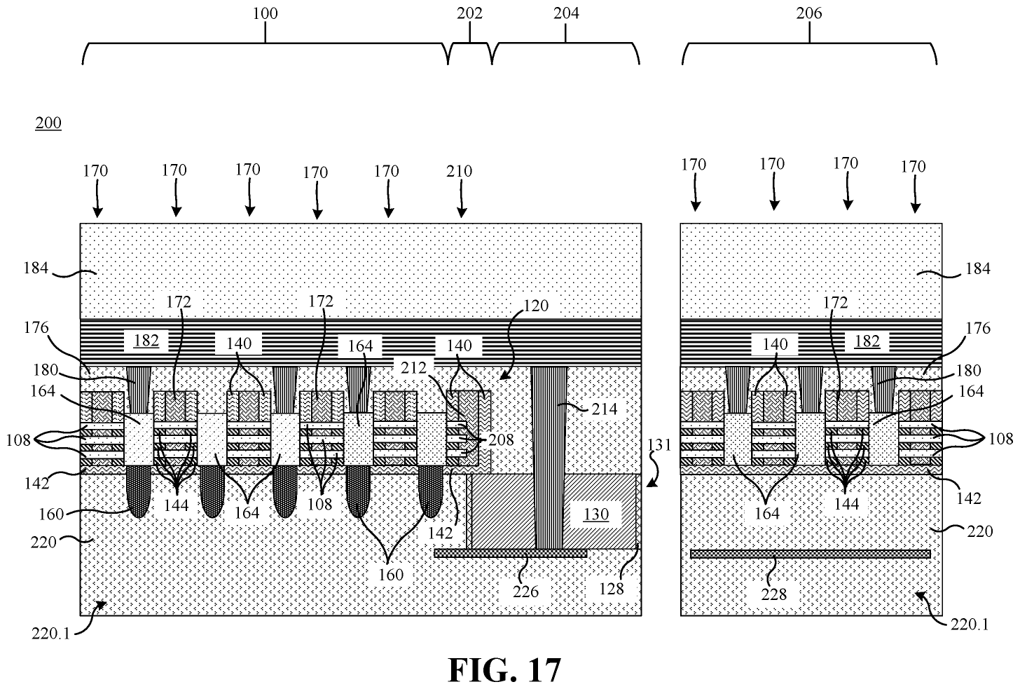

FIG. 17 depicts cross-sectional views of semiconductor IC device 200 shown after exemplary fabrication operation(s), in accordance with one or more embodiments. In the depicted fabrication stage, backside ILD 220.1 is formed upon the exposed backside of the semiconductor IC device 200.

The backside ILD 220.1 may be formed upon the bottom surfaces (as depicted) of the ILD 220, STI region(s), and around the respective exposed surfaces of the fuse wire 226 and backside wire 228. The backside ILD 220.1 may be formed by depositing a dielectric material, such as, for example, porous silicates, carbon doped oxides, silicon dioxides, silicon nitrides, silicon oxynitrides, or other dielectric materials. Any appropriate deposition technique for forming the backside ILD 220.1 can be utilized. The backside ILD 220.1 can be formed using, for example, CVD, PECVD, ALD, flowable CVD, spin-on dielectrics, or PVD. As depicted, backside ILD 220.1 may be formed of the same material as backside ILD 220. As such, backside ILD 220.1 and backside ILD 220 are cumulatively referred to as backside ILD 220, hereinafter.

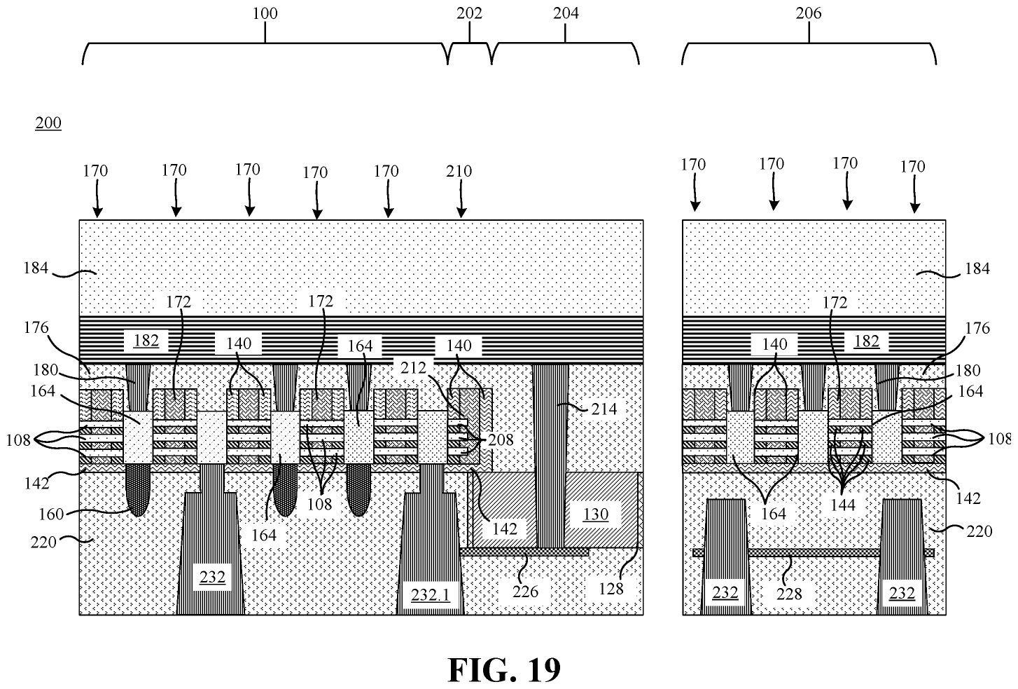

FIG. 18 depicts cross-sectional views of semiconductor IC device 200 shown after exemplary fabrication operation(s), in accordance with one or more embodiments. In the depicted fabrication stage, backside contact openings 230 are formed within backside ILD 220. For clarity, a particular backside contact opening 230.1 is depicted and is associated with the predetermined backside contact placeholder 160 and is further associated with the backside contact 232.1 (depicted in FIG. 19) that positionally allows for the backside contact 232.1 to connect with both the fuse wire 226 and the S/D region 164 located above the predetermined backside contact placeholder 160.

The backside contact openings 230 may be formed by the same or shared lithography and etch process(es), or sequential lithography and etch processes. In such process(es), a mask may be applied to the backside of the backside ILD 220 and patterned. Openings in the patterned mask may expose the portion of the underlying backside ILD 220 to be removed while other protected portions of semiconductor IC device 200 may be protected and retained. In such process(es), the dry and wet etching processes can have etching parameters that can be tuned, such as etchants used, etching temperature, etching solution concentration, etching pressure, source power, RF bias voltage, RF bias power, etchant flow rate, to promote desired material removal and desired material retention.

In the depicted example, within resistor region 206, two or more backside contact openings 230 may be formed within backside ILD 220 and through the backside wire 228. Further in the depicted example, within the semiconductor IC device 100 region, the backside contact opening 230.1 is formed within backside ILD 220 through fuse wire 226. This backside contact opening 230.1 further exposes the and/or partially removes a portion of the backside contact placeholder 160 there above (as depicted). Further in the depicted example, within the semiconductor IC device 100 region, one or more backside contact openings 230 are formed within backside ILD 220 that expose a respective and/or partially removes a portion of the respective backside contact placeholder 160 there above (as depicted). Subsequently, the exposed backside contact placeholders 160 may be removed by a substrative removal technique, such as an etch. In one example, the entire applicable contact placeholder 160 may be removed. In another example, the lower portion of the backside contact placeholder is removed using the etch stop layer top surface of the backside contact placeholder 160 as an etch stop to protect the S/D region 164 there above.

FIG. 19 depicts cross-sectional views of semiconductor IC device 200 shown after exemplary fabrication operation(s), in accordance with one or more embodiments. In the depicted fabrication stage, a backside contacts 232 is formed within the backside contact opening(s) 230.

For clarity, a particular backside contact 232.1 is depicted that positionally connects with both the fuse wire 226 and the S/D region 164 located there above. For example, a sidewall of the backside contact 232.1 contacts the fuse wire and a top surface of the backside contact 232.1 contacts the S/D region 164 there above (as depicted).

The backside contacts 232 may be further formed by depositing conductive material, such as metal, into the respective backside contact opening(s) 230. In an example, backside contacts 232 may be formed by depositing a liner, such as Ni, NiPt or Ti, etc. into the backside contact opening(s) 230, depositing a metal adhesion liner, such as TiN, TaN, etc. upon the liner, and by depositing a conductive metal fill, such as Al, Ru, W, Co, Cu, etc. upon the metal adhesion liner. Subsequently, a planarization process, such as a CMP process or a mechanical grinding process, may remove excess portions of the conductive barrier layer and the conductive material. Subsequently, the respective bottom surfaces (as depicted) of backside contacts 232 and backside ILD 220 may be substantially horizontal and/or substantially coplanar.

In the depicted example, within resistor region 206, two or more backside contacts 232 may contact the backside wire 228. For instance, a respective sidewall of each of the backside contacts 232 within the resistor region 206 may directly contact the backside wire 228. In certain examples, the backside wire 228 provides a predetermined resistance between the first backside contact 232 and the second backside contact 232 connected thereto. Further in the depicted example, within the semiconductor IC device 100 region, one or more backside contacts 232 connect with a respective S/D region 164 located there above (as depicted).

FIG. 20 depicts cross-sectional views of semiconductor IC device 200 shown after exemplary fabrication operation(s), in accordance with one or more embodiments. In the depicted fabrication stage, a backside BEOL network 240 is formed.

The backside BEOL network 240 is formed over the backside ILD 220 and upon the one or more backside contacts 232. The backside BEOL network 240 may be indirectly electrically and/or indirectly physically connected to the one or more S/D regions 164 by way of a particular backside contact 232. The backside BEOL network 240 is located directly on the backside surface of backside ILD 220, backside contacts 232, etc.

The backside BEOL network 240 can include one or more interconnect dielectric material layers (including one of the dielectric materials mentioned above for the frontside ILD layer 176) and contains backside metal wires embedded therein. In some embodiments, the backside metal wires within the backside BEOL network 240 are composed of Cu. The backside BEOL network 240 can include “x” numbers of backside metal levels, wherein “x” is an integer starting from 1. If not included in frontside BEOL network 182, backside BEOL network 240 may further contain conductive pads that are connected to one or more of the backside metal wires and may be used to connect the semiconductor IC device 200 to the external and/or higher-level structure.

In an example, signal routing and power routing is effectively split between the frontside BEOL network 182 and the backside BEOL network 240. For example, at least 90% of the frontside metal wires (e.g., furthest from the transistor(s)) are signal routing metal wires and the remainder frontside metal wires which are usually present in metal levels closest to the transistor, can be used as power routing wires. Further in this example, at least 90% of the backside metal wires that are in metal levels closest to the transistor(s) are power routing metal wires and the remainder backside metal wires which are usually present in metal levels furthest away from the transistor, can be used as signal routing wires. Power routing wires may be less dense signal routing wires. A signal routing wire is defined herein as a conductive feature, such as a wire, trace, or the like, that is configured to electrically carry a functional or logical potential or signal that is to change or is otherwise dynamic over time. A power routing wire is defined herein as a conductive feature, such as a wire, trace, plane, or the like, that is configured to electrically carry a logical potential that does not change over a predetermined time. For example, a power routing wire carries or otherwise has a functional power potential, such as VDD, VSS, or the like. For clarity, in some examples, the backside BEOL network 240 may be a backside power distribution network (BSPDN).

For clarity, semiconductor IC device 200 includes a fuse structure 235 which includes the fuse wire 226 and the deep via contact 214. The semiconductor IC device 200 further includes the backside contact 232.1. The backside contact 232.1 is connected to a transistor 250 (e.g., to S/D region 164.1 thereof), connected to the backside BEOL network 240, and is connected to the fuse wire 226. The fuse wire 226 is connected to the backside contact 232.1 and to the deep via contact 214. The deep via contact 214 is also connected to the frontside BEOL network 182.

In the non-programmed state of the fuse structure 235, the backside contact 232.1 may be utilized as a terminal for routing current for transistor 250 operation(s). Also, in the non-programmed state of the fuse structure 235, the backside contact 232.1 may be utilized as a terminal for routing current between frontside BEOL network 182 and backside BEOL network 240. To program the fuse structure 235, a programming voltage is applied to the deep via contact 214 that causes an open circuit failure within the fuse wire 226 (exemplary depicted in FIG. 1B) or within the backside contact 232.1 (exemplary depicted in FIG. 1C). Programming of the fuse structure 235 and the resulting open circuit failure within the fuse wire 226 may prevent functionality or operations of the semiconductor IC device 200 that are associated with current flow through the fuse structure 235. Alternatively, or in addition to, programming of the fuse structure 235 and the resulting open circuit failure within the backside contact 232.1 may prevent functionality or operations of the semiconductor IC device 200 that are associated with current flow through the fuse structure 235 and with current flow through transistor 250.

Semiconductor IC device 200 may be an integrated circuit (IC) chip. IC chips can be distributed by the fabricator in raw wafer form (that is, as a single wafer that has multiple unpackaged chips), as a bare die, or in a packaged form. In the latter case, the IC chip may mount in a single chip package (such as a plastic carrier, with leads that are affixed to a motherboard or other higher-level carrier) or in a multichip package (such as a ceramic carrier that has either or both surface interconnections or buried interconnections). In any case, the IC chip may be integrated with other chips, discrete circuit elements, and/or other signal processing devices as part of either (a) an intermediate product, such as a motherboard, or (b) an end product. The end product can be any product that includes the IC chip, ranging from toys and other low-end applications to advanced computer products having a display, a keyboard or other input device, and a central processor.

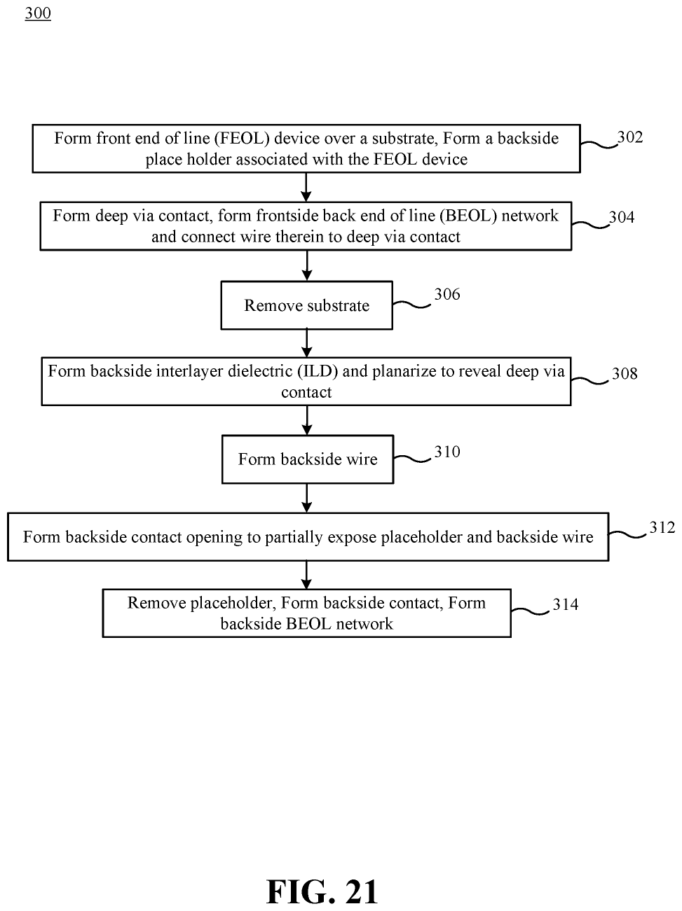

FIG. 21 depicts a flow diagram illustrating method 300 to fabricate a semiconductor IC device, such as semiconductor IC device 200. The depicted fabrication operations of method 300 are illustrated and described above with reference to one or more of FIG. 2 through FIG. 20 of the drawings, which describe the fabrication of semiconductor IC device 100 and the fabrication of semiconductor IC device 200, though the fabrication operations described in method 300 may be used to fabricate other types of semiconductor IC devices. The method 300 depicted herein is illustrative. There can be many variations to the diagram or operations described therein without departing from the spirit of the embodiments. For instance, the operations can be performed in a differing order, or operations can be added, deleted, or modified.

At block 302, method 300 may begin with forming a FEOL device over a substrate and forming a backside contact placeholder associated with the FEOL device. For example, method 300 may include forming a backside contact placeholder 160 and may include forming a GAA FET that includes active nanolayer 108 channels, S/D regions 164, replacement gate structure 170, and the like.

At block 304, method 300 may further continue with forming a deep via contact and with forming a frontside BEOL network that includes a routing wire therein that is connected to the deep via contact. For example, deep via contact 214 is formed along with frontside contact 180 that contacts one of the S/D regions 164.1 of the GAA FET transistor. Subsequently, frontside BEOL network 182 is formed upon the frontside of the semiconductor IC device. The BEOL network 182 includes a first routing wire (e.g., signal routing wire or power routing wire) that is connected to the deep via contact 214. The BEOL network 182 also includes a second routing wire, that is different from the first routing wire, that is connected to the frontside contact 180 that contacts one of the S/D regions 164.1 of the GAA FET transistor.

At block 306, method 300 may further continue with removing the substrate. For example, lower substrate 101, etch stop layer 103, and upper substrate 102 may be removed which may expose the backside contact placeholder 160.

At block 308, method 300 may further include forming a backside ILD and planarizing the backside of the semiconductor IC device to reveal the backside of the deep via contact. For example, backside ILD 220 is formed upon the backside of the semiconductor IC device 200 around the backside contact placeholder 160 and around the deep via contact 214 and the backside of the semiconductor IC device 200 is planarized to remove excess backside ILD 220 material and to reveal the backside of the deep via contact 214.

At block 310, method 300 may continue with forming a backside wire in contact with the deep via contact 214. For example, fuse wire 226 is formed upon the revealed backside of the deep via contact 214 and to a geometry in which a portion of the fuse wire is inset within and underneath the perimeter footprint of the backside contact placeholder 160.

At block 312, method 300 may continue with forming a backside contact opening to partially expose the backside contact placeholder and at least partially expose the backside wire. For example, backside contact opening 230.1 is formed within the backside ILD 210 to partially expose the backside contact placeholder 160 and to expose a portion of the fuse wire 226.

At block 314, method 300 may continue with removing the backside contact placeholder, with forming a backside contact within the backside contact opening, and with forming a backside BEOL network. For example, the backside contact placeholder 160 is removed which may expose the integrated etch stop layer there above (if present) or the S/D region 164.1 there above. The backside contact 232.1 is formed within the backside contact opening 230.1 to be in electrical contact with the fuse wire 226 and with the S/D region 164.1 there above. Next, the backside BEOL network 240 is formed upon the backside of semiconductor IC device 200. The backside BEOL network 240 includes a first routing wire (e.g., signal routing wire or power routing wire) that is connected to the backside contact 232.1.

The descriptions of the various embodiments have been presented for purposes of illustration and are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A semiconductor integrated circuit (IC) device comprising:
a fuse structure comprising a fuse wire and a deep via contact that is connected to the fuse wire and to a frontside back end of the line (BEOL) network; and
a backside contact that is connected to a transistor, to a backside BEOL network, and to the fuse wire.

2. The semiconductor IC device of claim 1, wherein the fuse wire is between the deep via contact and the backside BEOL network.

3. The semiconductor IC device of claim 1, wherein a top surface of the fuse wire is connected to a bottom surface of the deep via contact.

4. The semiconductor IC device of claim 1, wherein a side surface of the fuse wire is connected to a sidewall of the backside contact.

5. The semiconductor IC device of claim 1, wherein a top surface of the backside contact is connected to a source/drain (S/D) region of the transistor.

6. The semiconductor IC device of claim 1, wherein, when the fuse structure is in a non-programmed state, the backside contact is a terminal for routing current through the transistor and for routing current between the frontside BEOL network and the backside BEOL network by way of the fuse wire.

7. The semiconductor IC device of claim 1, wherein, when the fuse structure is in a programmed state, an open circuit exists within the fuse wire that prevents the fuse wire from routing current between the frontside BEOL network and the backside BEOL network.

8. The semiconductor IC device of claim 1, wherein, when the fuse structure is in a programmed state, an open circuit exists within the backside contact that prevents the backside contact from routing current through the transistor and the backside contact from routing current between the frontside BEOL network and the backside BEOL network by way of the fuse wire.

9. The semiconductor IC device of claim 1, wherein a diffusion break region is between the transistor and the deep via contact.

10. The semiconductor IC device of claim 1, wherein the fuse wire is underneath a shallow trench isolation (STI) region.

11. The semiconductor IC device of claim 1, wherein the fuse wire is coplanar with a backside resistor wire.

12. A semiconductor integrated circuit (IC) device method comprising:
programming a fuse structure that includes a fuse wire and a deep via contact, wherein the deep via contact is connected to the fuse wire and to a frontside back end of the line (BEOL) network, wherein the fuse wire is connected to a backside contact that is further connected to a transistor and to a backside BEOL network; and
as a result of programming the fuse structure, preventing current flow between the frontside BEOL network and a backside BEOL network through the fuse wire.

13. The semiconductor IC device method of claim 12, wherein the fuse wire is between the deep via contact and the backside BEOL network.

14. The semiconductor IC device method of claim 12, wherein a top surface of the fuse wire is connected to a bottom surface of the deep via contact.

15. The semiconductor IC device method of claim 12, wherein a side surface of the fuse wire is connected to a sidewall of the backside contact.

16. The semiconductor IC device method of claim 12, wherein a top surface of the backside contact is connected to a source/drain (S/D) region of the transistor.

17. A semiconductor integrated circuit (IC) device method comprising:
programming a fuse structure that includes a fuse wire and a deep via contact, wherein the deep via contact is connected to the fuse wire and to a frontside back end of the line (BEOL) network, wherein the fuse wire is connected to a backside contact that is further connected to a transistor and to a backside BEOL network; and
as a result of programming the fuse structure, preventing the backside contact from routing current through the transistor and the backside contact from routing current between the frontside BEOL network and the backside BEOL network by way of the fuse wire.

18. The semiconductor IC device method of claim 17, wherein the fuse wire is between the deep via contact and the backside BEOL network.

19. The semiconductor IC device method of claim 17, wherein a top surface of the fuse wire is connected to a bottom surface of the deep via contact.

20. The semiconductor IC device method of claim 17, wherein a side surface of the fuse wire is connected to a sidewall of the backside contact.
